(19) United States
(12) Patent Application Publication
(10) Pub. No.: US 2026/0190826 A1
(43) Pub. Date: Jul. 2, 2026

(54) LIGHT RECEIVING DEVICE, AUTOMOBILE AND ELECTRONIC DEVICE INCLUDING THE SAME

(71) Applicant: SAMSUNG DISPLAY CO., LTD., YONGIN-SI (KR)

(72) Inventors: Seo Young LIM, Yongin-si (KR); Gyeong Ub MOON, Yongin-si (KR); Seung Hyun MOON, Yongin-si (KR); Go Een JEONG, Yongin-si (KR); Soo Yeong HONG, Yongin-si (KR)

(21) Appl. No.: 19/352,565

(22) Filed: Oct. 8, 2025

(30) Foreign Application Priority Data
Dec. 26, 2024 (KR) 10-2024-0196543

(51) Int. Cl. H10K 59/80; H10K 39/34

(52) U.S. Cl. CPC H10K 59/8792; H10K 39/34

(57) ABSTRACT

A light receiving device includes a substrate including first and second areas, an element layer on the substrate and including a pixel defining film including first and second openings in the first and second areas, respectively, first and second light receiving areas respectively defined by the first and second openings, and an optical layer on the element layer and including a first light blocking layer and a light guide layer on the first light blocking layer. The first light blocking layer includes first light blocking patterns respectively including first transmission holes, the light guide layer includes first and second light guide patterns respectively including first and second light guide holes corresponding to the first and second openings, respectively. The first light guide hole overlaps the first opening in a plan view, and the second light guide hole is shifted with respect to the second opening in the plan view.

### CROSS-REFERENCE TO RELATED APPLICATION

This application claims priority under 35 U.S.C. § 119 to Korean Patent Application No. 10-2024-0196543, filed on Dec. 26, 2024 in the Korean Intellectual Property Office, the disclosure of which is incorporated by reference in its entirety herein.

### 1. TECHNICAL FIELD

The present disclosure relates to a light receiving device, an automobile and an electronic device including the same.

### 2. DISCUSSION OF RELATED ART

As the information society develops, functions of electronic devices have become increasingly diverse. Electronic devices may include various sensing devices to obtain external information. For example, the electronic device may obtain the external information by a visual method that senses light incident from the external environment.

A light detection and ranging (LiDAR) device is a type of sensing device that emits a laser pulse, receives light reflected and returned from a surrounding target object, and measures a distance to the surrounding target object, or the like. A general LiDAR device includes a controller, a transmission module, a reception module, and an optical module for beam steering.

Automobiles have been increasingly required to have higher safety and convenience, and various sensing devices have been utilized to realize the higher safety and convenience of the automobiles. Such sensing devices provide functions such as object sensing, distance measurement, lane keeping assistance, and blind spot warning using a light receiving device including light emitting elements and light receiving elements.

### SUMMARY

Aspects of embodiments of the present disclosure provide a light receiving device having a structure that is simple and manufacturing cost is reduced by further including light receiving elements in a display device, and an automobile including the same.

Aspects of embodiments of the present disclosure also provide a light receiving device in which quality and accuracy of sensing data are increased, and an automobile including the same.

However, aspects of embodiments of the present disclosure are not restricted to those set forth herein. The above and other aspects of embodiments of the present disclosure will become more apparent to one of ordinary skill in the art to which the present disclosure pertains by referencing the detailed description of the present disclosure given below.

According to an embodiment of the present disclosure, a light receiving device includes a substrate including a first area and a second area. An element layer is disposed on the substrate. The element layer includes a pixel defining film including a first opening disposed in the first area and a second opening disposed in the second area and a first light receiving area and a second light receiving area respectively defined by the first opening and the second opening. An optical layer is disposed on the element layer. The optical layer includes a first light blocking layer and a light guide layer disposed on the first light blocking layer. The first light blocking layer includes a plurality of first light blocking patterns respectively including a plurality of first transmission holes. The light guide layer includes a first light guide pattern including a first light guide hole corresponding to the first opening and a second light guide pattern including a second light guide hole corresponding to the second opening. The first light guide hole overlaps the first opening in a plan view, and the second light guide hole is shifted in one direction with respect to the second opening in the plan view.

In an embodiment, the first light guide hole completely overlaps the first light receiving area in the plan view, and the second light guide hole only partially overlaps or does not overlap the second light receiving area in the plan view.

In an embodiment, a first transmission hole corresponding to the first light guide hole among the plurality of first transmission holes completely overlaps the first light guide hole in the plan view, and a first transmission hole corresponding to the second light guide hole among the plurality of first transmission holes only partially overlaps or does not overlap the second light guide hole in the plan view.

In an embodiment, a size of the first light guide hole in the plan view is less than a size of a first transmission hole corresponding to the first opening among the plurality of first transmission holes in the plan view.

In an embodiment, a size of the first light guide hole in the plan view is less than a size of the first opening in the plan view.

In an embodiment, an inner side of the first light guide pattern is surrounded by a boundary of the first opening in the plan view.

In an embodiment, a size of a first transmission hole corresponding to the first opening among the plurality of first transmission holes in the plan view is greater than a size of the first opening in the plan view.

In an embodiment, an inner side of a first light blocking pattern corresponding to the first opening among the plurality of first light blocking patterns surrounds a boundary of the first opening in the plan view.

In an embodiment, the optical layer further includes a second light blocking layer disposed between the first light blocking layer and the light guide layer in a thickness direction of the light receiving device, the second light blocking layer including a plurality of second light blocking patterns respectively including a plurality of second transmission holes.

In an embodiment, a size of a second transmission hole corresponding to the first opening among the plurality of second transmission holes in the plan view is greater than a size of the first light guide hole in the plan view.

In an embodiment, a size of each of the plurality of second transmission holes in the plan view is equal to a size of the first transmission hole in the plan view.

In an embodiment, an overlap area between the first opening and the first light guide hole in the plan view is greater than an overlap area between the second opening and the second light guide hole in the plan view.

In an embodiment, the pixel defining film further includes a third opening spaced apart from the first opening and the second opening, the element layer includes an emission area defined by the third opening, and the emission area emits light of an infrared wavelength.

In an embodiment, the plurality of first light blocking patterns, the first light guide pattern, and the second light guide pattern do not overlap the emission area in the plan view.

In an embodiment, the first light receiving area and the second light receiving area collect light of an infrared wavelength, respectively.

According to an embodiment of the present disclosure, there is provided an automobile including, a body, and a first light receiving device disposed on the body, wherein the first light receiving device includes, a first substrate, a first element layer disposed on the first substrate and including a first pixel defining film including a first opening and a second opening and a first light receiving area and a second light receiving area respectively defined by the first opening and the second opening, and a first optical layer disposed on the first element layer and including a first light blocking layer and a first light guide layer disposed on the first light blocking layer, wherein the first light blocking layer includes a plurality of first light blocking patterns respectively including a plurality of first transmission holes. The first light guide layer includes a first light guide pattern including a first light guide hole corresponding to the first opening and a second light guide pattern including a second light guide hole corresponding to the second opening. The first light guide hole overlaps the first opening in a plan view, and the second light guide hole is shifted in a first direction with respect to the second opening in the plan view.

In an embodiment, the automobile may further comprise a second light receiving device located in a second direction opposite to the first direction of the first light receiving device, wherein the second light receiving device includes, a second substrate, a second element layer disposed on the second substrate and including a second pixel defining film including a third opening and a fourth opening spaced apart from each other and a third light receiving area and a fourth light receiving area respectively defined by the third opening and the fourth opening, and a second optical layer disposed on the second element layer and including a second light blocking layer and a second light guide layer disposed on the second light blocking layer. The second light blocking layer includes a plurality of second light blocking patterns respectively including a plurality of second transmission holes. The second light guide layer includes a third light guide pattern including a third light guide hole corresponding to the third opening and a fourth light guide pattern including a fourth light guide hole corresponding to the fourth opening. The third light guide hole overlaps the third opening in the plan view, and the fourth light guide hole is shifted in the second direction opposite to the first direction with respect to the fourth opening in the plan view.

In an embodiment, the first pixel defining film further includes a third opening located in a second direction opposite to the first direction with the first opening disposed between the second opening and the third opening in the plan view, the first element layer further includes a third light receiving area defined by the third opening, the first light guide layer further includes a third light guide pattern including a third light guide hole corresponding to the third opening, and the third light guide hole is shifted in the second direction with respect to the third opening in the plan view.

In an embodiment, the first light guide hole completely overlaps the first light receiving area, and the second light guide hole only partially overlaps or does not overlap the second light receiving area.

In an embodiment, an overlap area between the first opening and the first light guide hole is greater than an overlap area between the second opening and the second light guide hole.

According to an embodiment of the present disclosure, an electronic device includes a processor. A memory has stored application programs for execution by the processor. A light receiving device includes a substrate including a first area and a second area. An element layer is disposed on the substrate, the element layer including a pixel defining film including a first opening disposed in the first area and a second opening disposed in the second area and a first light receiving area and a second light receiving area respectively defined by the first opening and the second opening. An optical layer is disposed on the element layer. The optical layer includes a first light blocking layer and a light guide layer disposed on the first light blocking layer. The first light blocking layer includes a plurality of first light blocking patterns respectively including a plurality of first transmission holes. The light guide layer includes a first light guide pattern including a first light guide hole corresponding to the first opening and a second light guide pattern including a second light guide hole corresponding to the second opening. The first light guide hole overlaps the first opening in a plan view, and the second light guide hole is shifted in one direction with respect to the second opening in the plan view.

With an light receiving device and an automobile including the same according to an embodiment of the present disclosure, by further including light receiving elements in a display device, a structure of the light receiving device may be simple and a manufacturing cost of the light receiving device may be reduced.

With the light receiving device and the automobile including the same according to an embodiment of the present disclosure, quality and accuracy of sensing data may be increased.

The effects of the present disclosure are not limited to the aforementioned effects, and various other effects are included in the present specification.

### BRIEF DESCRIPTION OF THE DRAWINGS

The above and other aspects and features of the present disclosure will become more apparent by describing in detail non-limiting embodiments thereof with reference to the attached drawings, in which:

FIG. 1 is a perspective view illustrating an electronic device according to an embodiment;

FIG. 2 is a schematic view illustrating an operating state of an optical transmitting/receiving device according to an embodiment;

FIG. 3 is a perspective view illustrating an electronic device according to another embodiment;

FIG. 4 is a schematic view illustrating an operating state of an optical transmitting/receiving device according to an embodiment;

FIG. 5 is a perspective view illustrating the optical transmitting/receiving device according to an embodiment;

FIG. 6 is a cross-sectional view illustrating the optical transmitting/receiving device according to an embodiment;

FIG. 7 is a plan view illustrating light emitting pixels, light receiving pixels, various drivers, and various lines of the optical transmitting/receiving device according to an embodiment;

FIG. 8 is a block diagram illustrating the light emitting pixels, the light receiving pixels, the various drivers, and the various lines of the optical transmitting/receiving device according to an embodiment;

FIG. 9A is a circuit diagram illustrating an example of a light emitting pixel of the optical transmitting/receiving device according to an embodiment;

FIG. 9B is a circuit diagram illustrating another example of a light emitting pixel of the optical transmitting/receiving device according to an embodiment;

FIG. 10A is a cross-sectional view illustrating the light emitting pixel of the optical transmitting/receiving device according to an embodiment of FIG. 9A;

FIG. 10B is a cross-sectional view illustrating the light emitting pixel of the optical transmitting/receiving device according to an embodiment of FIG. 9B;

FIG. 11 is a circuit diagram illustrating a light receiving pixel of the optical transmitting/receiving device according to an embodiment;

FIG. 12 is a cross-sectional view illustrating the light receiving pixel of the optical transmitting/receiving device according to an embodiment;

FIG. 13 is a plan view illustrating emission areas and light receiving areas of the optical transmitting/receiving device according to an embodiment;

FIG. 14 is a plan view illustrating first light blocking layers disposed on the emission areas and the light receiving areas of the optical transmitting/receiving device according to an embodiment;

FIG. 15 is a plan view illustrating light guide layers disposed on the emission areas and the light receiving areas of the optical transmitting/receiving device according to an embodiment in a first area;

FIG. 16 is a plan view illustrating the first light blocking layers and the light guide layers disposed on the emission areas and the light receiving areas of the optical transmitting/receiving device according to an embodiment in the first area;

FIG. 17 is a cross-sectional view taken along line X1-X1′ of FIG. 16 according to an embodiment;

FIG. 18A is a plan view illustrating first light blocking layers and light guide layers disposed on the emission areas and the light receiving areas of the optical transmitting/receiving device according to an embodiment in a second-first area;

FIG. 18B is a plan view illustrating first light blocking layers and light guide layers disposed on the emission areas and the light receiving areas of the optical transmitting/receiving device according to an embodiment in a second-second area;

FIG. 19A is a cross-sectional view taken along line X2-X2′ of FIG. 18A according to an embodiment;

FIG. 19B is a cross-sectional view taken along line X3-X3′ of FIG. 18B according to an embodiment;

FIG. 20A is a schematic view illustrating a sensing range of the optical transmitting/receiving device according to an embodiment of FIG. 1;

FIG. 20B is a schematic view illustrating a sensing range of the optical transmitting/receiving device according to an embodiment of FIG. 3; and

FIG. 21 is a cross-sectional view illustrating an optical transmitting/receiving device according to an embodiment.

FIG. 22 is a diagram illustrating an electronic device according to an embodiment.

### DETAILED DESCRIPTION OF EMBODIMENTS

The present disclosure will now be described more fully hereinafter with reference to the accompanying drawings, in which non-limiting embodiments of the present disclosure are shown. The present disclosure may, however, be embodied in different forms and should not be construed as limited to the described embodiments set forth herein.

It will also be understood that when a layer is referred to as being “on” another layer or substrate, it can be directly on the other layer or substrate, or intervening layers may also be present. When a layer is referred to as being “directly on” another layer or substrate, no intervening layers may be present. The same reference numbers indicate the same components throughout the specification.

Hereinafter, embodiments of the present disclosure will be described in detail with reference to the accompanying drawings.

The present disclosure concerns a light receiving device that includes an element layer including light receiving areas defined by openings in a pixel defining film, an optical layer disposed above the light receiving areas and including light blocking layers having transmission holes and a light guide layer disposed above the light blocking layers and including light guide patterns having light guide holes. The light guide holes may have a relatively small size compared to the transmission holes and the openings defining the light receiving areas. Some light guide holes of the light guide layer may be shifted with respect to a corresponding light receiving area.

The light guide layer may increase the accuracy of the light receiving device by narrowing a sensing range of the light receiving elements of the light receiving device. The light blocking layer may block diffracted light passing through the light guide holes to increase the accuracy of the data sensed by the light receiving elements.

The sensing range of the light receiving device may be customized by the arrangement of the light guide holes with respect to corresponding light blocking layers and openings defining the light receiving areas to sense a specific area of an object. Therefore, the light receiving device may have increased accuracy for sensing particular portions of objects in the environment.

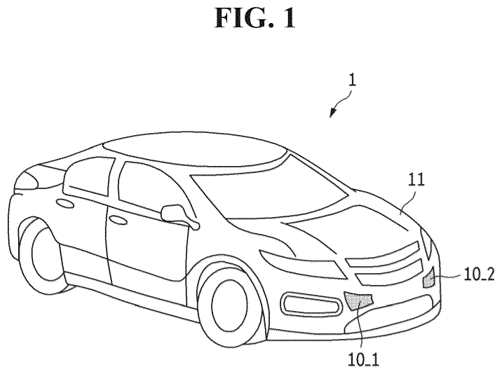

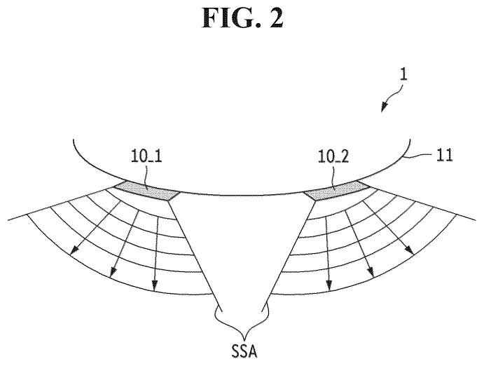

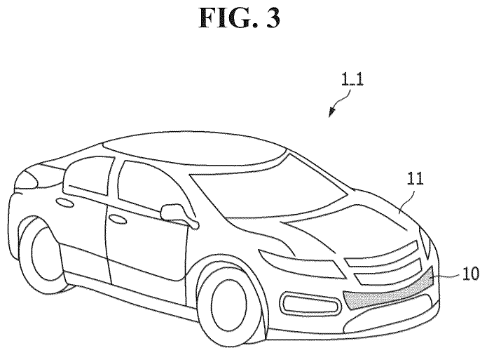

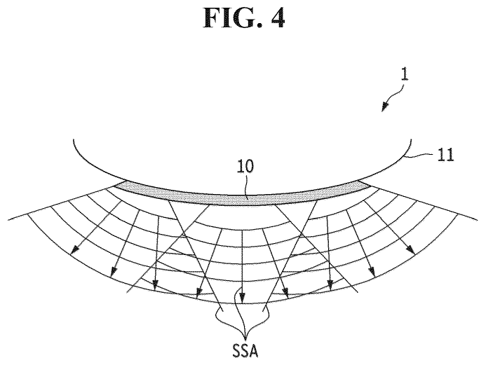

FIG. 1 is a perspective view illustrating an electronic device according to an embodiment. FIG. 2 is a schematic view illustrating an operating state of an optical transmitting/receiving device according to an embodiment. FIG. 3 is a perspective view illustrating an electronic device according to an embodiment. FIG. 4 is a schematic view illustrating an operating state of an optical transmitting/receiving device according to an embodiment.

Referring to FIGS. 1 to 4, in an embodiment an electronic device 1 may include optical transmitting/receiving devices 10_1 and 10_2. The electronic device 1 may sense a shape of an external object and a distance to the external object by including the optical transmitting/receiving devices 10_1 and 10_2.

For example, the optical transmitting/receiving devices 10_1 and 10_2 may include light emitting elements and light receiving elements. In an embodiment, the optical transmitting/receiving devices 10_1 and 10_2 may emit light through the light emitting elements, and may sense light reflected and returned from the external object through the light receiving elements. The electronic device 1 may sense the shape of the external object and the distance from the external object using sensing data of the optical transmitting/receiving devices 10_1 and 10_2.

In some embodiments, the optical transmitting/receiving devices 10_1 and 10_2 may sense the shape of the external object and the distance from the external object using infrared rays. For example, the optical transmitting/receiving devices 10_1 and 10_2 may include light emitting elements emitting infrared rays and light receiving elements receiving infrared rays.

In some embodiments, the electronic device 1 may be an automobile. When the electronic device 1 is the automobile, the electronic device 1 may include a body 11 constituting an outer appearance. However, the electronic device 1 is not necessarily limited to the automobile, and all small-sized, medium-sized and large-sized electronic devices to which the optical transmitting/receiving devices 10_1 and 10_2 may be applied to sense the external object may correspond to the electronic device 1.

The optical transmitting/receiving devices 10_1 and 10_2 may be disposed on the body 11 of the electronic device 1. As illustrated in FIGS. 1 and 2, in an embodiment at least two optical transmitting/receiving devices 10_1 and 10_2 may be provided and be spaced apart from each other on the body 11. For example, as illustrated in FIGS. 1 and 2, a plurality of optical transmitting/receiving devices 10_1 and 10_2 may be provided and spaced apart from each other, and may be located at specific points of the body 11. Accordingly, the respective optical transmitting/receiving device 10_1 and 10_2 may have sensing ranges SSA at different locations.

In some embodiments, as illustrated in FIGS. 3 and 4, an electronic device 1_1 according to an embodiment may include only one optical transmitting/receiving device 10. In this embodiment, the optical transmitting/receiving device 10 may be disposed continuously along a shape of the electronic device 1_1. For example, the optical transmitting/receiving device 10 may have a flexible shape to be disposed continuously along the shape of the electronic device 1_1. In some embodiments, when the electronic device 1_1 is an automobile, the optical transmitting/receiving device 10 may be disposed continuously along a shape of a body 11, such as the front side or front fender of the automobile.

As illustrated in FIG. 4, when the optical transmitting/receiving device 10 is disposed continuously, sensing ranges SSA of the optical transmitting/receiving device 10 may overlap each other in some areas. Accordingly, a blind spot that may not be sensed by the optical transmitting/receiving device 10 may be minimized or eliminated, and accuracy of data in overlapping areas may be increased.

In an embodiment, the optical transmitting/receiving device 10 may have a structure similar to a display panel of a display device. For example, the optical transmitting/receiving device 10 may further include light receiving elements in addition to existing light emitting elements of the display device. Like the display panel displaying an image through numerous individual pixels, the optical transmitting/receiving device 10 may accurately sense a surrounding object by including numerous light emitting pixels and light receiving pixels. For example, the respective light receiving pixels may collect data in a narrow range to increase accuracy, and numerous light receiving pixels may be disposed in high resolution and combine the respective sensing data with each other to collect a wider range of data.

In addition, when the optical transmitting/receiving device 10 includes the light receiving elements in addition to the existing light emitting elements of the display device, a structure of the optical transmitting/receiving device 10 may be simplified, and a manufacturing cost of the optical transmitting/receiving device 10 may be reduced.

Hereinafter, a specific structure of such an optical transmitting/receiving device 10 will be described.

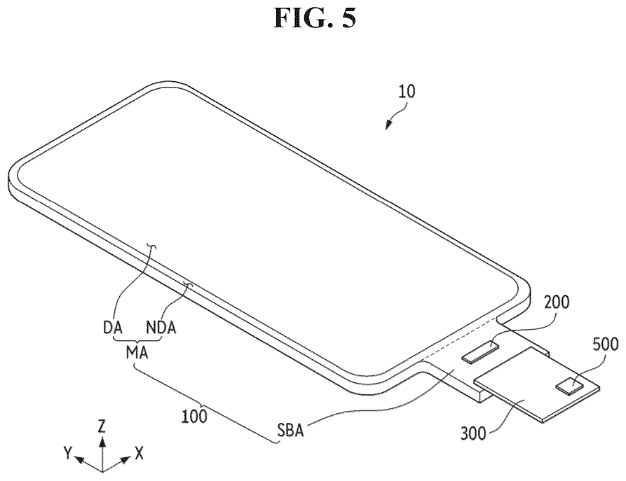

FIG. 5 is a perspective view illustrating the optical transmitting/receiving device according to an embodiment.

Referring to FIG. 5, the optical transmitting/receiving device 10 may have a shape similar to a rectangular shape in a plan view. For example, in an embodiment the optical transmitting/receiving device 10 may have a shape similar to a rectangular shape, in a plan view, having short sides in an X-axis direction and long sides in a Y-axis direction. A corner where the short side in the X-axis direction and the long side in the Y-axis direction meet may be rounded with a selected curvature or right-angled. However, a shape of the optical transmitting/receiving device 10 is not necessarily limited thereto, and the optical transmitting/receiving device 10 may have a shape similar to other polygonal shapes, a circular shape, or an elliptical shape in a plan view.

In some embodiments, as described above, the optical transmitting/receiving device 10 may be disposed along the shape (e.g., an outer shape) of the electronic device 1, and in this case, a shape of the optical transmitting/receiving device 10 may be changed into a shape corresponding to the shape of the electronic device 1. For example, when the shape of the electronic device 1 is a curved shape, the shape of the optical transmitting/receiving device 10 may be bent along the shape of the electronic device 1 and changed into a curved shape. For example, the optical transmitting/receiving device 10 may have a flexible shape.

In an embodiment, the optical transmitting/receiving device 10 may include an optical transmitting/receiving panel 100, a data driving circuit 200, a circuit board 300, and a power supply unit 500.

The optical transmitting/receiving panel 100 may include a main area MA and a sub-area SBA.

The main area MA may include a sensing area DA having light emitting pixels and light receiving pixels and a non-sensing area NDA disposed around the sensing area DA (e.g., in a plan view).

The sensing area DA may emit light through a plurality of emission areas or a plurality of opening areas. For example, the optical transmitting/receiving panel 100 may include light emitting pixel circuits including switching elements, a pixel defining film defining the emission areas or the opening areas, and self-light emitting elements.

For example, the self-light emitting element may include one of an organic light emitting diode (LED) including an organic light emitting layer, a quantum dot LED including a quantum dot light emitting layer, an inorganic LED including an inorganic semiconductor, and a micro LED, but is not necessarily limited thereto.

The sensing area DA may receive light through a plurality of light receiving areas. For example, the optical transmitting/receiving panel 100 may include light receiving pixel circuits including switching elements, the pixel defining film defining the light receiving areas, and light receiving elements. For example, the light receiving element may be an organic photodiode including an organic light receiving layer, but is not necessarily limited thereto.

The non-sensing area NDA may be an area outside the sensing area DA (e.g., in a plan view). The non-sensing area NDA may be defined as an edge area of the main area MA of the optical transmitting/receiving panel 100. In an embodiment, the non-sensing area NDA may include a gate driver supplying gate signals to gate lines and fan-out lines connecting the data driving circuit 200 and the sensing area DA to each other.

The sub-area SBA may extend from one side of the main area MA (e.g., a lower side in the Y-axis direction). The sub-area SBA may include a flexible material that may be bent, folded, and rolled. For example, when the sub-area SBA is bent, the sub-area SBA may overlap the main area MA in a thickness direction (e.g., the Z-axis direction). The sub-area SBA may include the data driving circuit 200 and pad portions connected to the circuit board 300. Alternatively, the sub-area SBA may be omitted, and the data driving circuit 200 and the pad portions may be disposed in the non-sensing area NDA.

The data driving circuit 200 may output signals and voltages for driving the optical transmitting/receiving panel 100. The data driving circuit 200 may supply data voltages to data lines. The data driving circuit 200 may supply a source voltage to a power line and supply a gate control signal to the gate driver. The data driving circuit 200 may receive a sensing signal through a lead-out line. In an embodiment, the data driving circuit 200 may be formed as an integrated circuit (IC) and mounted on the optical transmitting/receiving panel 100 in a chip on glass (COG) manner, a chip on plastic (COP) manner, or an ultrasonic bonding manner. As an example, the data driving circuit 200 may be disposed in the sub-area SBA, and may overlap the main area MA in the thickness direction (e.g., the Z-axis direction) by bending of the sub-area SBA. As another example, the data driving circuit 200 may be mounted on the circuit board 300.

In an embodiment, the circuit board 300 may be attached onto the pad portions of the optical transmitting/receiving panel 100 using an anisotropic conductive film (ACF). Lead lines of the circuit board 300 may be electrically connected to the pad portions of the optical transmitting/receiving panel 100. In an embodiment, the circuit board 300 may be a flexible printed circuit board, a printed circuit board, or a flexible film such as a chip on film.

The power supply unit 500 may be disposed on (e.g., disposed directly thereon) the circuit board 300 and may supply a source voltage to the data driving circuit 200 and the optical transmitting/receiving panel 100. The power supply unit 500 may generate a driving voltage and supply the driving voltage to a driving voltage line, and may generate a common voltage and supply the common voltage to a common electrode. For example, in an embodiment the driving voltage may be a high-potential voltage for driving the light emitting element, and the common voltage may be a low-potential voltage for driving the light emitting element. The power supply unit 500 may generate an initialization voltage and supply the initialization voltage to an initialization voltage line, may generate a reference voltage and supply the reference voltage to a reference voltage line, may generate a bias voltage and supply the bias voltage to a bias voltage line, and may generate a reset voltage and supply the reset voltage to a reset voltage line.

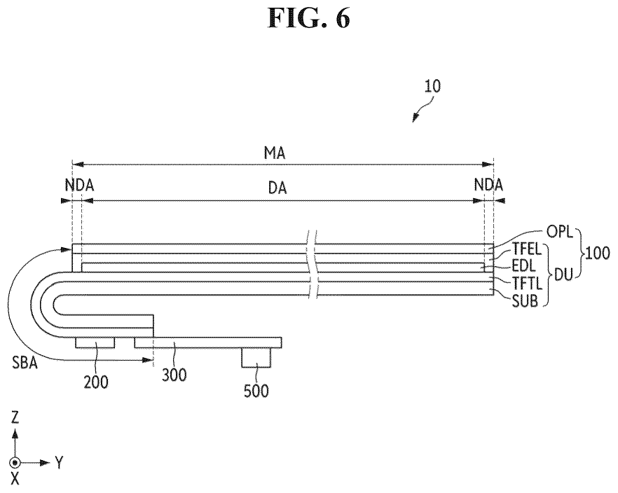

FIG. 6 is a cross-sectional view illustrating the optical transmitting/receiving device according to an embodiment.

Referring to FIG. 6, in an embodiment the optical transmitting/receiving device 10 may include an optical transmitting/receiving panel 100, a data driving circuit 200, a circuit board 300, and a power supply unit 500. In an embodiment, the optical transmitting/receiving panel 100 may include a sensor layer DU and an optical layer OPL. The sensor layer DU may include a substrate SUB, a transistor layer TFTL, an element layer EDL, and an encapsulation layer TFEL (e.g., consecutively stacked in the Z-axis direction).

The substrate SUB may be a base substrate or a base member. In an embodiment, the substrate SUB may be a flexible substrate that may be bent, folded, rolled or otherwise deformed. As an example, the substrate SUB may include a polymer resin such as polyimide, but is not necessarily limited thereto. As another example, the substrate SUB may include a glass material or a metal material.

The transistor layer TFTL may be disposed on the substrate SUB (e.g., disposed directly thereon in the Z-axis direction). The transistor layer TFTL may include a plurality of transistors constituting light emitting pixels and light receiving pixels. The transistor layer TFTL may further include gate lines, data lines, power lines, lead-out lines, gate control lines, fan-out lines connecting the data driving circuit 200 and the data lines to each other, and lead lines connecting the display data 200 and the pad portions to each other. Each of the transistors may include a semiconductor region, a source electrode, a drain electrode, and a gate electrode. For example, when a gate driver is formed on one side of the non-sensing area NDA of the optical transmitting/receiving panel 100, the gate driver may include transistors.

The transistor layer TFTL may be disposed in the sensing area DA, the non-sensing area NDA, and the sub-area SBA. The transistors, the gate lines, the data lines, the power lines, and the lead-out lines of the transistor layer TFTL may be disposed in the sensing area DA. The gate control lines and the fan-out lines of the transistor layer TFTL may be disposed in the non-sensing area NDA. The lead lines of the transistor layer TFTL may be disposed in the sub-area SBA.

In the optical transmitting/receiving device 10 according to an embodiment, by disposing light emitting pixel circuits driving the light emitting elements and light receiving pixel circuits driving the light receiving elements together in the transistor layer TFTL, it is possible to implement the optical transmitting/receiving device 10 having a structure that is simple and manufacturing cost is reduced. For example, the light emitting pixel circuit and the light receiving pixel circuit may share line layers and insulating layer included in the transistor layer TFTL with each other, and a line forming process of the light emitting pixel circuit and a line forming process of the light receiving pixel circuit may be simultaneously or continuously performed. For example, since only a light receiving pixel circuit forming process needs to be added to a manufacturing process of an existing display device, the manufacturing cost of the optical transmitting/receiving device 10 may be reduced, and some layers may be shared, such that the structure of the optical transmitting/receiving device 10 may be simplified.

The element layer EDL may be disposed on the transistor layer TFTL (e.g., disposed directly thereon in the Z-axis direction). The element layer EDL may include light emitting elements of light emitting pixels, light receiving elements of light receiving pixels, and a pixel defining film defining the light emitting pixels and the light receiving pixels. The light emitting element may emit light by including a pixel electrode, a light emitting layer, and a common electrode that are sequentially stacked (e.g., in the Z-axis direction), and the light receiving element may receive light by including a sensor electrode, a light receiving layer, and a common electrode that are sequentially stacked (e.g., in the Z-axis direction). The light emitting elements and light receiving elements of the element layer EDL may be disposed in the sensing area DA.

For example, in an embodiment the light emitting layer may be an organic light emitting layer including an organic material. In an embodiment the light emitting layer may include a hole transporting layer, an organic light emitting layer, and an electron transporting layer. When the pixel electrode receives a selected voltage through the transistor of the transistor layer TFTL and the common electrode receives a cathode voltage, holes and electrons may move to the organic light emitting layer through the hole transporting layer and the electrode transporting layer, respectively, and may combine with each other in the organic light emitting layer to emit light. For example, the pixel electrode may be an anode electrode and the common electrode may be a cathode electrode, but the present disclosure is not necessarily limited thereto.

As another example, a plurality of light emitting elements may include quantum dot light emitting diodes each including a quantum dot light emitting layer, inorganic light emitting diodes each including an inorganic semiconductor, or micro light emitting diodes.

The light receiving element may receive light and convert light energy into an electrical signal. When an object is located on the optical transmitting/receiving panel 100, the light emitted from the light emitting element may be reflected by the object, and the light receiving element may receive the reflected light. The light receiving pixel receiving the light reflected by the object may generate a sensing signal. In an embodiment, a main processor may generate sensing data based on such a sensing signal, and may determine a shape of the object, a distance to the object, or the like, based on the sensing data. For example, the light receiving element may be an organic photodiode, but is not necessarily limited thereto.

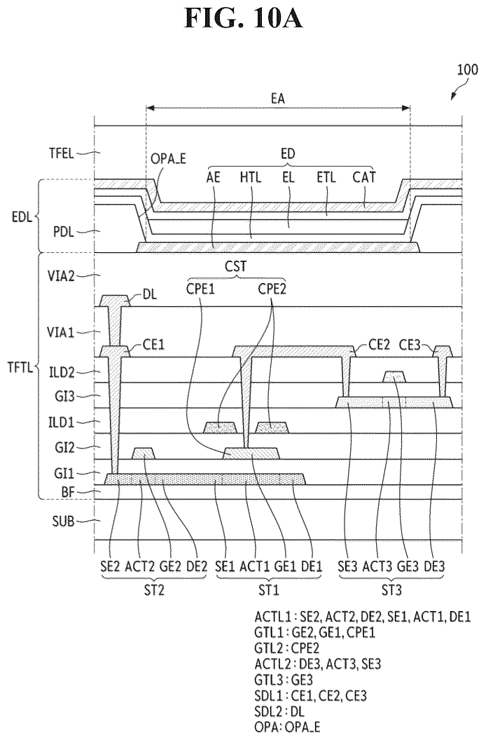

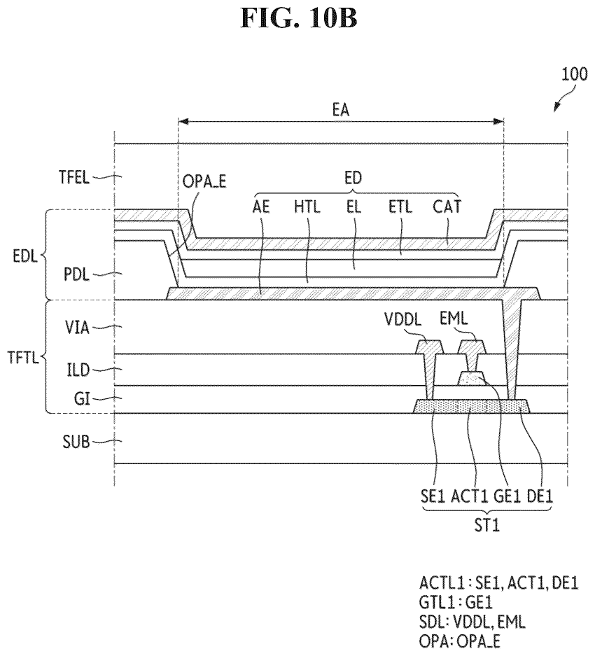

In the optical transmitting/receiving device 10 according to an embodiment, by disposing the light emitting elements and the light receiving elements together in the element layer EDL, it is possible to implement the optical transmitting/receiving device 10 having a structure that is simple and manufacturing cost is reduced. For example, a deposition process for forming a light emitting layer EL of the light emitting element and a deposition process for forming a light receiving layer RCL of the light receiving element may be simultaneously or continuously performed. In addition, layers such as a hole transporting layer HCL (see FIG. 10A), an electron transporting layer ETL (see FIG. 10A), and a common electrode CAT to be described later may be shared. For example, since only a light receiving element forming process needs to be added to the manufacturing process of the existing display device, the manufacturing cost of the optical transmitting/receiving device 10 may be reduced, and some layers may be shared, such that the structure of the optical transmitting/receiving device 10 may be simplified.

The encapsulation layer TFEL may cover an upper surface and side surfaces of the element layer EDL, and may protect the element layer EDL. In an embodiment, the encapsulation layer TFEL may include at least one inorganic film and at least one organic film for encapsulating the element layer EDL.

The optical layer OPL may be disposed on the encapsulation layer TFEL (e.g., disposed directly thereon in the Z-axis direction). The optical layer OPL may include light blocking patterns and transmission hole located to correspond to the light receiving pixels of the sensor layer DU. The optical transmitting/receiving device 10 may sense a wider angular range and may increase accuracy of the sensing data by further including the optical layer OPL.

The sub-area SBA of the optical transmitting/receiving panel 100 may extend from one side of the main area MA (e.g., a lower side in the Y direction). The sub-area SBA may include a flexible material that may be bent, folded, and rolled. For example, when the sub-area SBA is bent, the sub-area SBA may overlap the main area MA in the thickness direction of the optical transmitting/receiving panel 100 (e.g., the Z-axis direction). The sub-area SBA may include the data driving circuit 200 and the pad portions connected to the circuit board 300.

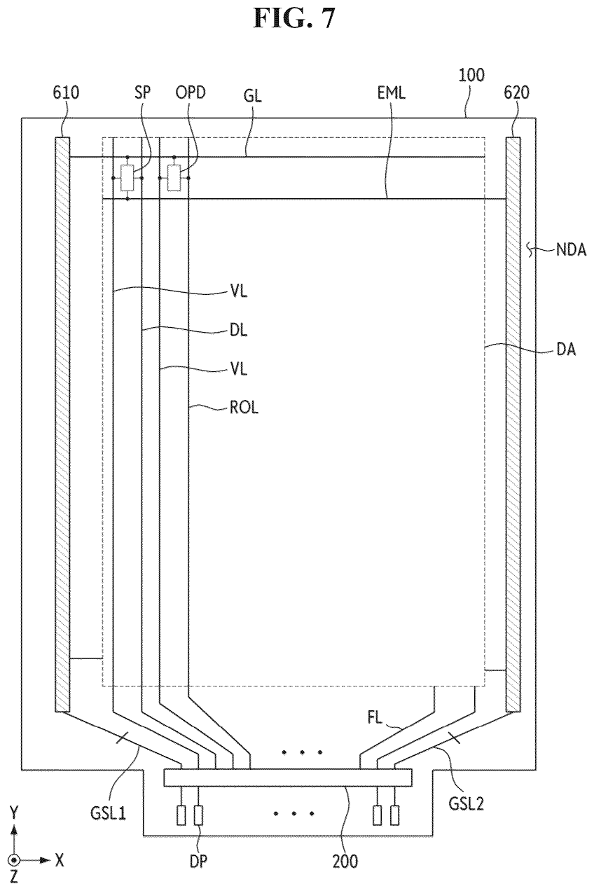

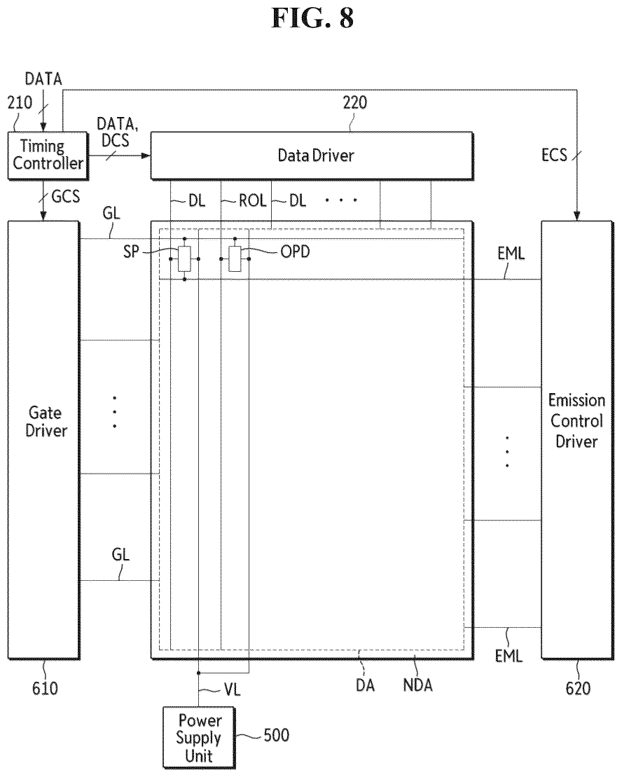

FIG. 7 is a plan view illustrating light emitting pixels, light receiving pixels, various drivers, and various lines of the optical transmitting/receiving device according to an embodiment. FIG. 8 is a block diagram illustrating the light emitting pixels, the light receiving pixels, the various drivers, and the various lines of the optical transmitting/receiving device according to an embodiment.

Referring to FIGS. 7 and 8, the optical transmitting/receiving panel 100 may include a sensing area DA and a non-sensing area NDA. The sensing area DA may include light emitting pixels SP, light receiving pixels OPD, power lines VL, data lines DL, read-out lines ROL, gate lines GL, and emission control lines EML.

Each of a plurality of light emitting pixels SP may be connected to the gate line GL, the emission control line EML, the data line DL, and the power line VL. Each of the plurality of light emitting pixels SP may include a plurality of transistors, a light emitting element, and a capacitor.

Each of a plurality of light receiving pixels OPD may be connected to the gate line GL, the power line VL, and the read-out line ROL. Each of the plurality of light receiving pixels OPD may include a plurality of transistors and a light receiving element.

In an embodiment, the gate lines GL may extend in the X-axis direction, and may be spaced apart from each other in the Y-axis direction crossing the X-axis direction. For example, in an embodiment the X-axis direction, Y-axis direction and Z-axis direction may be perpendicular to each other. However, embodiments of the present disclosure are not necessarily limited thereto and the X-axis direction, Y-axis direction and Z-axis direction may intersect each other at various different angles. The gate lines GL may sequentially supply gate signals to the light emitting pixels SP and the light receiving pixels OPD.

In an embodiment, the emission control lines EML may extend in the X-axis direction, and may be spaced apart from each other in the Y-axis direction. The emission control lines EML may sequentially supply emission signals to the light emitting pixels SP.

In an embodiment, the data lines DL may extend in the Y-axis direction, and may be spaced apart from each other in the X-axis direction. The data lines DL may supply data voltages to the light emitting pixels SP. The data voltage may determine luminance of each of the light emitting pixels SP.

In an embodiment, the power lines VL may extend in the Y-axis direction, and may be spaced apart from each other in the X-axis direction. The power line VL may supply source voltages to the light emitting pixels SP and the light receiving pixels OPD. In an embodiment, the source voltage may be a driving voltage, a common voltage, an initialization voltage, a reference voltage, a bias voltage, or a reset voltage. The driving voltage may be a high-potential voltage for driving the light emitting pixel SP, and the common voltage may be a low-potential voltage for driving the light emitting pixel SP and the light receiving pixel OPD.

The non-sensing area NDA may surround the sensing area DA (e.g., in a plan view). In an embodiment, the non-sensing area NDA may include a gate driver 610, an emission control driver 620, fan-out lines FL, a first gate control line GSL1, and a second gate control line GSL2.

The fan-out lines FL may extend from the data driving circuit 200 to the sensing area DA. The fan-out lines FL may supply data voltages received from the data driving circuit 200 to the data lines DL, supply source voltages received from the data driving circuit 200 to the power lines VL, and supply sensing signals received from the read-out lines ROL to the data driving circuit 200. Accordingly, the data driving circuit 200 may drive the light emitting pixels SP and the light receiving pixels OPD.

The first gate control line GSL1 may extend from the data driving circuit 200 to the gate driver 610. The first gate control line GSL1 may supply a gate control signal GCS received from the data driving circuit 200 to the gate driver 610.

The second gate control line GSL2 may extend from the data driving circuit 200 to the emission control driver 620. The second gate control line GSL2 may supply an emission control signal ECS received from the data driving circuit 200 to the emission control driver 620.

The sub-area SBA may extend from one side of the non-sensing area NDA (e.g., a lower side in the Y-axis direction). The sub-area SBA may include the data driving circuit 200 and pad portions DP. The pad portion DP may be located closer an edge of one side of the sub-area SBA (e.g., a lower edge in the Y-axis direction) than the data driving circuit 200. The pad portion DP may be electrically connected to the circuit board 300 through an anisotropic conductive film (ACF).

The data driving circuit 200 may include a timing controller 210 and a data driver 220.

The timing controller 210 may receive optical transmitting/receiving data DATA and timing signals from the circuit board 300. The timing controller 210 may generate a data control signal DCS based on the timing signals and supply the optical transmitting/receiving data DATA and the data control signal DCS to the data driver 220 to control an operation timing of the data driver 220. In an embodiment, the timing controller 210 may generate a gate control signal GCS and supply the gate control signal GCS to the gate driver 610, and may control an operation timing of the gate driver 610. The timing controller 210 may generate an emission control signal ECS and supply the emission control signal ECS to the emission control driver 620, and may control an operation timing of the emission control driver 620.

The data driver 220 may convert the optical transmitting/receiving data DATA into light emitting voltages and supply the light emitting voltages to the data lines DL through the fan-out lines FL. Gate signals of the gate driver 610 may select light emitting pixels SP to which the data voltages are supplied, and the selected light emitting pixels SP may receive the data voltages through the data lines DL. The data driver 220 may supply the sensing signals received through the read-out lines ROL to the main processor.

The power supply unit 500 may be disposed on the circuit board 300 and may supply a source voltage to the data driving circuit 200 and the optical transmitting/receiving panel 100. The power supply unit 500 may generate source voltages and supply the source voltages to the power lines VL, and may generate a common voltage and supply the common voltage to a common electrode common to the light emitting pixels SP and the light receiving pixels OPD. In an embodiment, the power supply unit 500 may generate an initialization voltage and supply the initialization voltage to an initialization voltage line, may generate a reference voltage and supply the reference voltage to a reference voltage line, may generate a bias voltage and supply the bias voltage to a bias voltage line, and may generate a reset voltage and supply the reset voltage to a reset voltage line.

In an embodiment, the gate driver 610 may be disposed outside one side of the sensing area DA or on one side of the non-sensing area NDA, and the emission control driver 620 may be disposed outside the other side (e.g., an opposite side) of the sensing area DA or on the other side (e.g., an opposite side) of the non-sensing area NDA, but the present disclosure is not necessarily limited thereto. As another example, the gate driver 610 and the emission control driver 620 may be disposed on any one of one side and the other side (e.g., an opposite side) of the non-sensing area NDA.

The gate driver 610 may include a plurality of transistors generating gate signals based on the gate control signal GCS. The emission control driver 620 may include a plurality of transistors generating emission signals based on the emission control signal ECS. For example, in an embodiment the transistors of the gate driver 610 and the transistors of the emission control driver 620 may be formed at a same layer as the transistor of each of the light emitting pixels SP. The gate driver 610 may supply the gate signals to the gate lines GL, and the emission control driver 620 may supply the emission signals to the emission control lines EML.

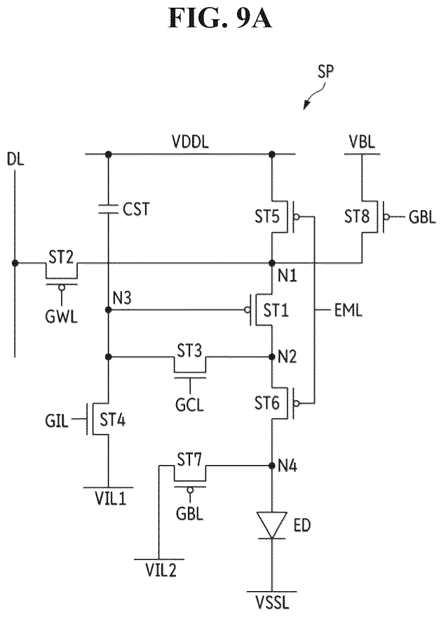

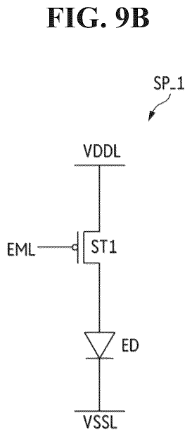

FIG. 9A is a circuit diagram illustrating an example of a light emitting pixel of the optical transmitting/receiving device according to an embodiment.

Referring to FIG. 9A, in an embodiment a light emitting pixel SP may be connected to a first gate line GWL, a second gate line GCL, a third gate line GIL, a fourth gate line GBL, an emission control line EML, a data line DL, a driving voltage line VDDL, a first initialization voltage line VIL1, a second initialization voltage line VIL2, a bias voltage line VBL, and a low-potential line VSSL.

The light emitting pixel SP may include a light emitting element ED and a light emitting pixel circuit driving the light emitting element ED. In an embodiment, the light emitting pixel circuit may include first to eighth transistors ST1, ST2, ST3, ST4, ST5, ST6, ST7, and ST8 and a capacitor CST. However, embodiments of the present disclosure are not necessarily limited thereto and the number of the transistors and arrangement thereof may vary.

The first transistor ST1 may control a driving current supplied to the light emitting element ED. The first transistor ST1 may include a gate electrode, a first electrode, and a second electrode. The gate electrode of the first transistor ST1 may be connected to a third node N3, the first electrode of the first transistor ST1 may be connected to a first node N1, and the second electrode of the first transistor ST1 may be connected to a second node N2. For example, the first electrode of the first transistor ST1 may be a source electrode and the second electrode of the first transistor ST1 may be a drain electrode, but the present disclosure is not necessarily limited thereto.

In an embodiment, the first transistor ST1 may control a source-drain current (hereinafter referred to as a “driving current”) according to a data voltage applied to the gate electrode. The driving current Isd flowing through a channel of the first transistor ST1 may be proportional to the square of a difference between a voltage Vsg between the source electrode and the gate electrode and a threshold voltage Vth of the first transistor ST1 (Isd=k×(Vsg−Vth)²). Here, k refers to a proportional coefficient determined by a structure and physical properties of the first transistor ST1, Vsg refers to a source-gate voltage of the first transistor ST1, and Vth refers to the threshold voltage of the first transistor ST1.

The light emitting element ED may receive the driving current to emit light. A light emission amount or luminance of the light emitting element ED may be proportional to a magnitude of the driving current. The light emitting element ED may include a first electrode, a second electrode, and a light emitting layer disposed between the first electrode and the second electrode (e.g., in a Z-axis direction). The first electrode of the light emitting element ED may be connected to a fourth node N4. The first electrode of the light emitting element ED may be connected to a second electrode of the sixth transistor ST6 and a first electrode of the seventh transistor ST7 through the fourth node N4. The second electrode of the light emitting element ED may be electrically connected to the low-potential line VSSL. The second electrode of the light emitting element ED may receive a low-potential voltage from the low-potential line VSSL. For example, in an embodiment the first electrode of the light emitting element ED may be an anode electrode or a pixel electrode and the second electrode of the light emitting element ED may be a cathode electrode or a common electrode, but the present disclosure is not necessarily limited thereto.

In an embodiment, the second transistor ST2 may be turned on by a first gate signal of the first gate line GWL to electrically connect the data line DL and the first node N1, which is the first electrode of the first transistor ST1, to each other. The second transistor ST2 may be turned on based on the first gate signal to supply a data voltage to the first node N1. A gate electrode of the second transistor ST2 may be connected to the first gate line GWL, a first electrode of the second transistor ST2 may be connected to the data line DL, and a second electrode of the second transistor ST2 may be connected to the first node N1. The second electrode of the second transistor ST2 may be connected to the first electrode of the first transistor ST1, a second electrode of the fifth transistor ST5, and a second electrode of the eighth transistor ST8 through the first node N1. For example, the first electrode of the second transistor ST2 may be a source electrode and the second electrode of the second transistor ST2 may be a drain electrode, but the present disclosure is not necessarily limited thereto.

In an embodiment, the third transistor ST3 may be turned on by a second gate signal of the second gate line GCL to electrically connect the second node N2, which is the second electrode of the first transistor ST1, and the third node N3, which is the gate electrode of the first transistor ST1, to each other. A gate electrode of the third transistor ST3 may be connected to the second gate line GCL, a first electrode of the third transistor ST3 may be connected to the second node N2, and a second electrode of the third transistor ST3 may be connected to the third node N3. The first electrode of the third transistor ST3 may be connected to the second electrode of the first transistor ST1 and a first electrode of the sixth transistor ST6 through the second node N2. The second electrode of the third transistor ST3 may be connected to the gate electrode of the first transistor ST1, a first electrode of the fourth transistor ST4, and a first capacitor electrode of the capacitor CST through the third node N3. For example, the first electrode of the third transistor ST3 may be a drain electrode and the second electrode of the third transistor ST3 may be a source electrode, but the present disclosure is not limited thereto.

In an embodiment, the fourth transistor ST4 may be turned on by a third gate signal of the third gate line GIL to electrically connect the third node N3, which is the gate electrode of the first transistor ST1, and the first initialization voltage line VIL1 to each other. The fourth transistor ST4 may be turned on based on the third gate signal to discharge the gate electrode of the first transistor ST1 to a first initialization voltage. A gate electrode of the fourth transistor ST4 may be connected to the third gate line GIL, the first electrode of the fourth transistor ST4 may be connected to the third node N3, and a second electrode of the fourth transistor ST4 may be connected to the first initialization voltage line VIL1. The first electrode of the third transistor ST4 may be connected to the gate electrode of the first transistor ST1, the second electrode of the third transistor ST3, and the first capacitor electrode of the capacitor CST through the third node N3. For example, the first electrode of the fourth transistor ST4 may be a drain electrode and the second electrode of the fourth transistor ST4 may be a source electrode, but the present disclosure is not necessarily limited thereto.

In an embodiment, the fifth transistor ST5 may be turned on by an emission signal of the emission control line EML to electrically connect the driving voltage line VDDL and the first node N1, which is the first electrode of the first transistor ST1, to each other. A gate electrode of the fifth transistor ST5 may be connected to the emission control line EML, a first electrode of the fifth transistor ST5 may be connected to the driving voltage line VDDL, and the second electrode of the fifth transistor ST5 may be connected to the first node N1. The second electrode of the fifth transistor ST5 may be electrically connected to the first electrode of the first transistor ST1, the second electrode of the second transistor ST2, and the second electrode of the eighth transistor ST8 through the first node N1. For example, in an embodiment the first electrode of the fifth transistor ST5 may be a source electrode and the second electrode of the fifth transistor ST5 may be a drain electrode, but the present disclosure is not necessarily limited thereto.

In an embodiment, the sixth transistor ST6 may be turned on by the emission signal of the emission control line EML to electrically connect the second node N2, which is the second electrode of the first transistor ST1, and the fourth node N4, which is the first electrode of the light emitting element ED, to each other. A gate electrode of the sixth transistor ST6 may be connected to the emission control line EML, the first electrode of the sixth transistor ST6 may be connected to the second node N2, and the second electrode of the sixth transistor ST6 may be connected to the fourth node N4. The first electrode of the sixth transistor ST6 may be connected to the second electrode of the first transistor ST1 and the first electrode of the third transistor ST3 through the second node N2. The second electrode of the sixth transistor ST6 may be connected to the first electrode of the light emitting element ED and the first electrode of the seventh transistor ST7 through the fourth node N4. For example, in an embodiment the first electrode of the sixth transistor ST6 may be a source electrode and the second electrode of the sixth transistor ST6 may be a drain electrode, but the present disclosure is not necessarily limited thereto.

When the fifth transistor ST5, the first transistor ST1, and the sixth transistor ST6 are all turned on, the driving current Isd may be supplied to the light emitting element ED.

In an embodiment, the seventh transistor ST7 may be turned on by a fourth gate signal of the fourth gate line GBL to electrically connect the second initialization voltage line VIL2 and the fourth node N4, which is the first electrode of the light emitting element ED, to each other. The seventh transistor ST7 may be turned on based on the fourth gate signal to discharge the first electrode of the light emitting element ED to a second initialization voltage. A gate electrode of the seventh transistor ST7 may be connected to the fourth gate line GBL, the first electrode of the seventh transistor ST7 may be connected to the fourth node N4, and a second electrode of the seventh transistor ST7 may be connected to the second initialization voltage line VIL2. The first electrode of the seventh transistor ST7 may be connected to the first electrode of the light emitting element ED and the second electrode of the sixth transistor ST6 through the fourth node N4. For example, the first electrode of the seventh transistor ST7 may be a source electrode and the second electrode of the seventh transistor ST7 may be a drain electrode, but the present disclosure is not necessarily limited thereto.

In an embodiment, the eighth transistor ST8 may be turned on by the fourth gate signal of the fourth gate line GBL to electrically connect the bias voltage line VBL and the first node N1, which is the first electrode of the first transistor ST1, to each other. A gate electrode of the eighth transistor ST8 may be connected to the fourth gate line GBL, a first electrode of the eighth transistor ST8 may be connected to the bias voltage line VBL, and the second electrode of the eighth transistor ST8 may be connected to the first node N1. The second electrode of the eighth transistor ST8 may be electrically connected to the first electrode of the first transistor ST1, the second electrode of the second transistor ST2, and the second electrode of the fifth transistor ST5 through the first node N1. For example, in an embodiment the first electrode of the eighth transistor ST8 may be a source electrode and the second electrode of the eighth transistor ST8 may be a drain electrode, but the present disclosure is not necessarily limited thereto. Optionally, the eighth transistor ST8 may be omitted.

In an embodiment, each of the first transistor ST1, the second transistor ST2, the fifth transistor ST5, the sixth transistor ST6, the seventh transistor ST7, and the eighth transistor ST8 may include a silicon-based semiconductor region. For example, each of the first transistor ST1, the second transistor ST2, the fifth transistor ST5, the sixth transistor ST6, the seventh transistor ST7, and the eighth transistor ST8 may include a semiconductor region made of low temperature polycrystalline silicon (LTPS). The semiconductor region made of the low temperature polycrystalline silicon may have high electron mobility and excellent turn-on characteristics. Accordingly, the optical transmitting/receiving device 10 may stably and efficiently drive the plurality of light emitting pixels SP by including the first transistor ST1, the second transistor ST2, the fifth transistor ST5, the sixth transistor ST6, the seventh transistor ST7, and the eighth transistor ST8 that have the excellent turn-on characteristics.

In an embodiment, each of the first transistor ST1, the second transistor ST2, the fifth transistor ST5, the sixth transistor ST6, the seventh transistor ST7, and the eighth transistor ST8 may correspond to a P-type transistor. For example, each of the first transistor ST1, the second transistor ST2, the fifth transistor ST5, the sixth transistor ST6, the seventh transistor ST7, and the eighth transistor ST8 may output a current introduced into the first electrode to the second electrode based on a gate low voltage applied to the gate electrode.

In an embodiment, each of the third transistor ST3 and the fourth transistor ST4 may include an oxide-based semiconductor region. For example, each of the third transistor ST3 and the fourth transistor ST4 may have a coplanar structure in which the gate electrode is disposed above the oxide-based semiconductor region. The transistor having the coplanar structure may have excellent leakage current characteristics, and may be driven at a low frequency to reduce power consumption. Accordingly, the optical transmitting/receiving device 10 may prevent a leakage current from flowing inside the light emitting pixel and stably maintain a voltage inside the light emitting pixel by including the third transistor ST3 and the fourth transistor ST4 that have the excellent leakage current characteristics.

In an embodiment, each of the third transistor ST3 and fourth transistor ST4 may correspond to an N-type transistor. For example, each of the third transistor ST3 and the fourth transistor ST4 may output a current introduced into the first electrode to the second electrode based on a gate high voltage applied to the gate electrode.

The capacitor CST may be connected between the third node N3, which is the gate electrode of the first transistor ST1, and the driving voltage line VDDL. For example, the capacitor CST may have the first capacitor electrode connected to the third node N3 and a second capacitor electrode connected to the driving voltage line VDDL to maintain a potential difference between the driving voltage line VDDL and the gate electrode of the first transistor ST1.

FIG. 9B is a circuit diagram illustrating another example of a light emitting pixel of the optical transmitting/receiving device according to an embodiment.

Referring to FIG. 9B, a light emitting pixel SP_1 according to an embodiment may be connected to a driving voltage line VDDL, a low-potential line VSSL, and an emission control line EML for driving a light emitting element ED, like an embodiment of FIG. 9A. In addition, the light emitting pixel SP_1 may include a light emitting element ED and a light emitting pixel circuit driving the light emitting element ED.

However, the light emitting pixel circuit of the light emitting pixel SP_1 according to an embodiment may include one driving transistor for driving the light emitting element ED, unlike an embodiment of FIG. 9A. For example, the light emitting pixel circuit of the light emitting pixel SP_1 may include a first transistor ST1.

The first transistor ST1 may control a driving current supplied to the light emitting element ED. The first transistor ST1 may include a gate electrode, a first electrode, and a second electrode. The gate electrode of the first transistor ST1 may be connected to the emission control line EML, the first electrode of the first transistor ST1 may be connected to the driving voltage line VDDL, and the second electrode of the first transistor ST1 may be connected to the light emitting element ED. For example, in an embodiment the first electrode of the first transistor ST1 may be a drain electrode and the second electrode of the first transistor ST1 may be a source electrode, but the present disclosure is not necessarily limited thereto.

In an embodiment, the first transistor ST1 may be turned on by an emission control signal of the emission control line EML to electrically connect the first electrode and the second electrode of the first transistor ST1 to each other. The first transistor ST1 may supply the driving current to the light emitting element ED by the emission control signal of the emission control line EML.

The light emitting element ED may receive the driving current to emit light. A light emission amount or luminance of the light emitting element ED may be proportional to a magnitude of the driving current. The light emitting element ED may include a first electrode, a second electrode, and a light emitting layer disposed between the first electrode and the second electrode (e.g., in the Z-axis direction). The first electrode of the light emitting element ED may be electrically connected to the first transistor ST1, and the second electrode of the light emitting element ED may be electrically connected to the low-potential line VSSL. For example, in an embodiment the first electrode of the light emitting element ED may be an anode electrode or a pixel electrode and the second electrode of the light emitting element ED may be a cathode electrode or a common electrode, but the present disclosure is not necessarily limited thereto.

FIG. 10A is a cross-sectional view illustrating the light emitting pixel of the optical transmitting/receiving device according to an embodiment.

Referring to FIG. 10A in addition to FIG. 9A, in an embodiment the optical transmitting/receiving panel 100 may include a substrate SUB, a transistor layer TFTL, an element layer EDL, and an encapsulation layer TFEL. The light emitting pixel SP may include a light emitting pixel circuit and a light emitting element ED. The light emitting pixel circuit may be disposed in the transistor layer TFTL, and the light emitting element ED may be disposed in the element layer EDL.

The substrate SUB may be a base substrate or a base member. In an embodiment, the substrate SUB may be a flexible substrate that may be bent, folded, rolled or otherwise deformed. As an example, in an embodiment the substrate SUB may include a polymer resin such as polyimide, but is not necessarily limited thereto. As another example, the substrate SUB may include a glass material or a metal material.

In an embodiment, the transistor layer TFTL may include a buffer layer BF, a first active layer ACTL1, a first gate insulating layer GI1, a first gate layer GTL1, a second gate insulating layer GI2, a second gate layer GTL2, a first interlayer insulating layer ILD1, a second active layer ACTL2, a third gate insulating layer GI3, a third gate layer GTL3, a second interlayer insulating layer ILD2, a first source metal layer SDL1, a first via layer VIA1, a second source metal layer SDL2, and a second via layer VIA2.

The buffer layer BF may be disposed on (e.g., disposed directly thereon) the substrate SUB. For example, the buffer layer BF may include an inorganic film capable of preventing permeation of air or moisture. For example, the buffer layer BF may include a plurality of inorganic films that are alternately stacked (e.g., in the Z-axis direction).

The first active layer ACTL1 may be disposed on (e.g., disposed directly thereon) the buffer layer BF. In an embodiment, the first active layer ACTL1 may include a silicon-based material. For example, the first active layer ACTL1 may be made of low temperature polycrystalline silicon (LTPS). The first active layer ACTL1 may include a semiconductor region ACT1, a first electrode SE1, and a second electrode DE1 of the first transistor ST1, and a semiconductor region ACT2, a first electrode SE2, and a second electrode DE2 of the second transistor ST2.

The first gate insulating layer GI1 may be disposed on (e.g., disposed directly thereon) the first active layer ACTL1. The first gate insulating layer GI1 may insulate the first active layer ACTL1 and the first gate layer GTL1 from each other.

The first gate layer GTL1 may be disposed on (e.g., disposed directly thereon) the first gate insulating layer GI1. In an embodiment, the first gate layer GTL1 may include a gate electrode GE1 of the first transistor ST1, a gate electrode GE2 of the second transistor ST2, and a first capacitor electrode CPE1. In an embodiment, the gate electrode GE1 of the first transistor ST1 may be a portion of the first capacitor electrode CPE1, and the gate electrode GE2 of the second transistor ST2 may be a portion of the first gate line GWL.

The second gate insulating layer GI2 may be disposed on (e.g., disposed directly thereon) the first gate layer GTL1. The second gate insulating layer GI2 may insulate the first gate layer GTL1 and the second gate layer GTL2 from each other.

The second gate layer GTL2 may be disposed on (e.g., disposed directly thereon) the second gate insulating layer GI2. In an embodiment, the second gate layer GTL2 may include a second capacitor electrode CPE2. The second capacitor electrode CPE2 may overlap the first capacitor electrode CPE1 (e.g., in a thickness direction of the optical transmitting/receiving panel 100).

The first interlayer insulating layer ILD1 may be disposed on (e.g., disposed directly thereon) the second gate layer GTL2. The first interlayer insulating layer ILD1 may insulate the second gate layer GTL2 and the second active layer ACTL2 from each other.

The second active layer ACTL2 may be disposed on (e.g., disposed directly thereon) the first interlayer insulating layer ILD1. The second active layer ACTL2 may include an oxide-based material. The second active layer ACTL2 may include a semiconductor region ACT3, a first electrode DE3, and a second electrode SE3 of the third transistor ST3.

The third gate insulating layer GI3 may be disposed on (e.g., disposed directly thereon) the second active layer ACTL2. The third gate insulating layer GI3 may insulate the second active layer ACTL2 and the third gate layer GTL3 from each other.

The third gate layer GTL3 may be disposed on (e.g., disposed directly thereon) the third gate insulating layer GI3. In an embodiment, the third gate layer GTL3 may include a gate electrode GE3 of the third transistor ST3. The gate electrode GE3 of the third transistor ST3 may be a portion of the second gate line GCL.

The second interlayer insulating layer ILD2 may be disposed on (e.g., disposed directly thereon) the third gate layer GTL3. The second interlayer insulating layer ILD2 may insulate the third gate layer GTL3 and the first source metal layer SDL1 from each other.

The first source metal layer SDL1 may be disposed on (e.g., disposed directly thereon) the second interlayer insulating layer ILD2. In an embodiment, the first source metal layer SDL1 may include first to third connection electrodes CE1, CE2, and CE3. The first connection electrode CE1 may electrically connect the data line DL and the first electrode SE2 of the second transistor ST2 to each other. The second connection electrode CE2 may electrically connect the first capacitor electrode CPE1 and the second electrode SE3 of the third transistor ST3 to each other. The third connection electrode CE3 may electrically connect the first electrode DE3 of the third transistor ST3 and the second electrode DE1 of the first transistor ST1 to each other.

The first via layer VIA1 may be disposed on (e.g., disposed directly thereon) the first source metal layer SDL1. The first via layer VIA1 may insulate the first source metal layer SDL1 and the second source metal layer SDL2 from each other. An upper surface of the first via layer VIA1 may be flat. In an embodiment, the first via layer VIA1 may include an organic insulating material such as polyimide.

The second source metal layer SDL2 may be disposed on (e.g., disposed directly thereon) the first via layer VIA1. In an embodiment, the second source metal layer SDL2 may include the data line DL.

The second via layer VIA2 may be disposed on (e.g., disposed directly thereon) the second source metal layer SDL2. The second via layer VIA2 may insulate the second source metal layer SDL2 and a pixel electrode AE from each other. An upper surface of the second via layer VIA2 may be flat. The second via layer VIA2 may include an organic insulating material such as polyimide.

The element layer EDL may include a pixel defining film PDL and the light emitting element ED.

The pixel defining film PDL may be disposed on (e.g., disposed directly thereon) the second via layer VIA2. The pixel defining film PDL may define a plurality of emission areas EA. The pixel defining film PDL may include an organic insulating material such as polyimide, but is not necessarily limited thereto.

The pixel defining film PDL may include a plurality of openings OPA. The plurality of openings OPA of the pixel defining film PDL may at least partially expose upper surfaces of the pixel electrodes AE of the light emitting elements ED. In some embodiments, the plurality of openings OPA may include emission openings OPA_E overlapping the pixel electrodes AE.

The light emitting element ED may include the pixel electrode AE, a hole transporting layer HTL, a light emitting layer EL, an electron transporting layer ETL, and a common electrode CAT. The pixel electrode AE may be disposed on (e.g., disposed directly thereon) the second via layer VIA2. The pixel electrode AE may overlap (e.g., in a thickness direction of the optical transmitting/receiving panel 100) one of the plurality of emission areas EA defined by the pixel defining film PDL. The pixel electrode AE may receive the driving current from the light emitting pixel circuit of the light emitting pixel SP.

The plurality of emission areas EA may be areas defined by the emission openings OPA_E. For example, the plurality of emission areas EA may be areas where the light emitting layers EL overlap (e.g., in a thickness direction of the optical transmitting/receiving panel 100) the pixel electrodes AE within a plurality of emission openings OPA_E.

The hole transporting layer HTL may be disposed on (e.g., disposed directly thereon) the pixel electrode AE in the emission area EA and disposed on the pixel defining film PDL in an area other than the emission area EA. In an embodiment, the hole transporting layer HTL is not divided for each light emitting pixel SP, and may be implemented as a common layer for all light emitting pixels SP and light receiving pixels OPD.

The light emitting layer EL may be disposed on (e.g., disposed directly thereon) the hole transporting layer HTL in the emission area EA. For example, in an embodiment the light emitting layer EL may be an organic light emitting layer made of an organic material, but is not necessarily limited thereto. In some embodiments, the light emitting layer EL may include an organic material emitting light of an infrared wavelength. For example, the light emitting layer EL may emit light of a wavelength greater than or equal to 700 nm.

The electron transporting layer ETL may be disposed on (e.g., disposed directly thereon) the light emitting layer EL in the emission area EA and disposed on (e.g., disposed directly thereon) the hole transporting layer HTL in the area other than the emission area EA. In an embodiment, the electron transporting layer ETL is not divided for each light emitting pixel SP, and may be implemented as a common layer for all light emitting pixels SP and light receiving pixels OPD.

The common electrode CAT may be disposed on (e.g., disposed directly thereon) the electron transporting layer ETL. For example, in an embodiment the common electrode CAT is not divided for each of the plurality of light emitting pixels SP, and may be implemented in the form of an electrode common to all light emitting pixels SP and light receiving pixels OPD. The common electrode CAT may be a transparent electrode, and may transmit light. The common electrode CAT may be electrically connected to the low-potential line VSSL, and may receive a low-potential voltage, a common voltage, or a cathode voltage.

In an embodiment in which the light emitting layer EL is the organic light emitting layer, when the light emitting pixel circuit of the light emitting pixel SP applies a selected voltage to the pixel electrode AE and the common electrode CAT receives the common voltage or the cathode voltage, holes and electrons may move to the light emitting layer EL through the hole transporting layer HTL and the electron transporting layer ETL, respectively, and may be combined with each other in the light emitting layer EL to emit light.

The encapsulation layer TFEL may be disposed on (e.g., disposed directly thereon) the common electrodes CAT to cover a plurality of light emitting elements ED. In an embodiment, the encapsulation layer TFEL may include at least one inorganic film to prevent oxygen or moisture from permeating into the plurality of light emitting elements ED. The encapsulation layer TFEL may include at least one organic film to protect the plurality of light emitting elements ED from foreign substances such as dust.

FIG. 10B is a cross-sectional view illustrating the light emitting pixel of the optical transmitting/receiving device according to an embodiment of FIG. 9B. In relation to FIG. 10B, same components as those of an embodiment described with reference to FIG. 10A will be denoted by same reference numerals and an overlapping description thereof will be omitted or simplified, and contents different from those of an embodiment described with reference to FIG. 10A will be mainly described for economy of explanation.

Referring to FIG. 10B in addition to FIG. 9B, the optical transmitting/receiving panel 100 may include a substrate SUB, a transistor layer TFTL, an element layer EDL, and an encapsulation layer TFEL. The light emitting pixel SP_1 may include a light emitting pixel circuit and a light emitting element ED. The light emitting pixel circuit may be disposed in the transistor layer TFTL, and the light emitting element ED may be disposed in the element layer EDL. The substrate SUB, the element layer EDL, and the encapsulation layer TFEL are the same as those described with reference to FIG. 10A, and a description thereof is thus omitted.

In an embodiment, the transistor layer TFTL may include an active layer ACTL1, a gate insulating layer GI, a gate layer GTL1, an interlayer insulating layer ILD, a source metal layer SDL, and a via layer VIA. In an embodiment, the transistor layer TFTL may further include a buffer layer BF disposed between the substrate SUB and the active layer ACTL.

The active layer ACTL may be substantially the same layer as the first active layer ACTL1 of FIG. 10A, the gate insulating layer GI may be substantially the same layer as the first gate insulating layer GI1 of FIG. 10A, the gate layer GTL may be substantially the same layer as the first gate layer GTL1 of FIG. 10A, the interlayer insulating layer ILD may be substantially the same layer as the first interlayer insulating layer ILD1 of FIG. 10A, the source metal layer SDL may be substantially the same layer as the first source metal layer SDL1 of FIG. 10A, and the via layer VIA may be substantially the same layer as the first via layer VIA1 of FIG. 10A.

In an embodiment, the active layer ACTL may include a semiconductor region ACT1, a first electrode SE1, and a second electrode DE1 of the first transistor ST1. The gate layer GTL may include a gate electrode GE1 of the first transistor ST1. The source metal layer SDL may include the driving voltage line VDDL and the emission control line EML. In an embodiment, the emission control line EML may be connected to the gate electrode GE1 of the first transistor ST1 through a contact hole in the interlayer insulating layer ILD. The driving voltage line VDDL may be connected to the first electrode SE1 of the first transistor ST1 through a contact hole in the interlayer insulating layer and the gate insulating layer GI.

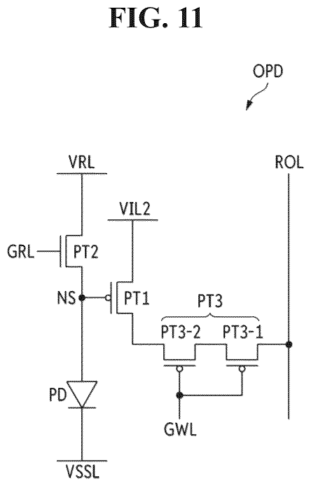

FIG. 11 is a circuit diagram illustrating a light receiving pixel of the optical transmitting/receiving device according to an embodiment.

Referring to FIG. 11, in an embodiment the light receiving pixel OPD may be connected to a first gate line GWL, a reset signal line GRL, a reset voltage line VRL, a second initialization voltage line VIL2, a low-potential line VSSL, and a read-out line ROL.

The light receiving pixel OPD may include a light receiving element PD and a light receiving pixel circuit driving the light receiving element PD. The light receiving pixel circuit may include first to third sensor transistors PT1, PT2, and PT3. However, embodiments of the present disclosure are not necessarily limited thereto and the number of the transistors included in the light receiving pixel circuit may vary.

The first sensor transistor PT1 may include a gate electrode, a first electrode, and a second electrode. The gate electrode of the first sensor transistor PT1 may be connected to a sensor node NS, the first electrode of the first sensor transistor PT1 may be connected to the third sensor transistor PT3, and the second electrode of the first sensor transistor PT1 may be connected to the second initialization voltage line VIL2. The first sensor transistor PT1 may control a source-drain current Isd (hereinafter referred to as a “sensing current”) based on a voltage of the sensor node NS, which is a first electrode of the light receiving element PD. The sensing current Isd flowing through a channel of the first sensor transistor PT1 may be proportional to the square of a difference between a voltage Vsg between a source electrode and the gate electrode and a threshold voltage Vth of the first sensor transistor PT1 (Isd=k′×(Vsg−Vth)²). Here, k′ refers to a proportional coefficient determined by a structure and physical properties of the first sensor transistor PT1, Vsg refers to a source-gate voltage of the first sensor transistor PT1, and Vth refers to the threshold voltage of the first sensor transistor PT1. In an embodiment, the first electrode of the first sensor transistor PT1 may be a source electrode and the second electrode of the first sensor transistor PT1 may be a drain electrode, but the present disclosure is not necessarily limited thereto.

In an embodiment, the second sensor transistor PT2 may be turned on by a reset signal of the reset signal line GRL to discharge the voltage of the sensor node NS to a reset voltage. A gate electrode of the second sensor transistor PT2 may be connected to the reset signal line GRL, a first electrode of the second sensor transistor PT2 may be connected to the sensor node NS, and a second electrode of the second sensor transistor PT2 may be connected to the reset voltage line VRL. The first electrode of the second sensor transistor PT2 may be connected to the first electrode of the light receiving element PD and the gate electrode of the first sensor transistor PT1 through the sensor node NS. In an embodiment, the first electrode of the of the second sensor transistor PT2 may be a drain electrode and the second electrode of the second sensor transistor PT2 may be a source electrode, but the present disclosure is not necessarily limited thereto.

In an embodiment, the third sensor transistor PT3 may be turned on by a first gate signal of the first gate line GWL to electrically connect the first electrode of the first sensor transistor PT1 and the read-out line ROL to each other. In an embodiment, the third sensor transistor PT3 may include a third-first sensor transistor PT3-1 and a third-second sensor transistor PT3-2 connected to each other in series. The third-first sensor transistor PT3-1 and the third-second sensor transistor PT3-2 may be connected to each other in series between the first electrode of the first sensor transistor PT1 and the read-out line ROL. In an embodiment, a gate electrode of the third-first sensor transistor PT3-1 and a gate electrode of the third-second sensor transistor PT3-2 may be formed integrally with each other and electrically connected to the first gate line GWL. A first electrode of the third-first sensor transistor PT3-1 may be connected to the lead-out line ROL, and a second electrode of the third-second sensor transistor PT3-2 may be connected to the first electrode of the first sensor transistor PT1. In an embodiment, a second electrode of the third-first sensor transistor PT3-1 and a first electrode of the third-second sensor transistor PT3-2 may be formed integrally with each other. The first electrode of each of the third-first sensor transistor PT3-1 and the third-second sensor transistor PT3-2 may be a source electrode and the second electrode of each of the third-first sensor transistor PT3-1 and the third-second sensor transistor PT3-2 may be a drain electrode, but the present disclosure is not necessarily limited thereto.

The light receiving element PD may receive light and convert light energy into an electrical signal. The first electrode of the light receiving element PD may be connected to the sensor node NS, which is the gate electrode of the first sensor transistor PT1, and a second electrode of the light receiving element PD may be connected to the low-potential line VSSL. The second electrode of the light receiving element PD may receive a low-potential voltage from the low-potential line VSSL. For example, in an embodiment the first electrode of the light receiving element PD may be a sensor electrode and the second electrode of the light receiving element PD may be a common electrode, but the present disclosure is not necessarily limited thereto.

When an object is located on the optical transmitting/receiving panel 100, the light emitted from the light emitting element may be reflected by the object, and the light receiving element PD may receive the reflected light. The light receiving element PD may convert energy of the light into an electrical signal (e.g., a current or a voltage) formed between the first electrode and the second electrode, and the converted electrical signal may flow from the low-potential line VSSL to the sensor node NS as a reverse bias current. For example, when the light receiving element PD receives the light and an electric field is formed between the first electrode and the second electrode of the light receiving element PD, a current may flow in the light receiving element PD in proportion to an amount of the light, and the voltage of the sensor node NS may increase. Accordingly, when the light receiving element PD receives the light, the voltage of the sensor node NS may increase, and a magnitude of the sensing current (or the source-drain current) of the first sensor transistor PT1 may decrease. In an embodiment, the sensing current of the first sensor transistor PT1 may be applied to the data driving circuit 200 as a sensing signal through the third sensor transistor PT3 and the read-out line ROL.

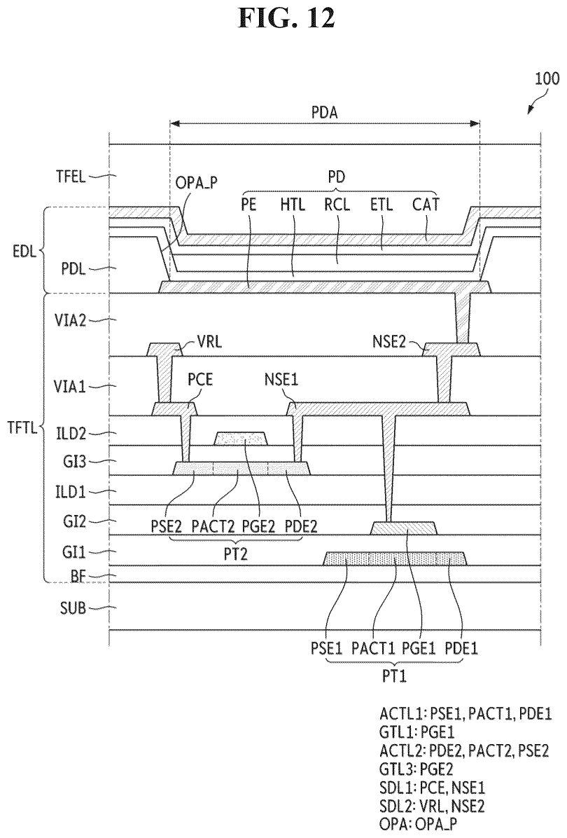

FIG. 12 is a cross-sectional view illustrating the light receiving pixel of the optical transmitting/receiving device according to an embodiment.

Referring to FIG. 12 in addition to FIG. 11, in an embodiment the optical transmitting/receiving panel 100 may include a substrate SUB, a transistor layer TFTL, an element layer EDL, and an encapsulation layer TFEL. The light receiving pixel OPD may include a light receiving pixel circuit and a light receiving element PD. The light receiving pixel circuit may be disposed in the transistor layer TFTL, and the light receiving element PD may be disposed in the element layer EDL.

The substrate SUB and the encapsulation layer TFEL have been described above with reference to FIG. 10A, and a description thereof is thus omitted for economy of explanation.

In an embodiment, the transistor layer TFTL may include a buffer layer BF, a first active layer ACTL1, a first gate insulating layer GI1, a first gate layer GTL1, a second gate insulating layer GI2, a first interlayer insulating layer ILD1, a second active layer ACTL2, a third gate insulating layer GI3, a third gate layer GTL3, a second interlayer insulating layer ILD2, a first source metal layer SDL1, a first via layer VIA1, a second source metal layer SDL2, and a second via layer VIA2.

The buffer layer BF, the first gate insulating layer GI1, the second gate insulating layer GI2, the first interlayer insulating layer ILD1, the third gate insulating layer GI3, the second interlayer insulating layer ILD2, the first via layer VIA1, and the second via layer VIA2 of the transistor layer TFTL have been described above with reference to FIG. 10A, and a description thereof is thus omitted for economy of explanation.

The first active layer ACTL1 may be disposed on (e.g., disposed directly thereon) the buffer layer BF. In an embodiment, the first active layer ACTL1 may include a silicon-based material. For example, the first active layer ACTL1 may be made of low temperature polycrystalline silicon (LTPS). The first active layer ACTL1 may include a semiconductor region PACT1, a first electrode PSE1, and a second electrode PDE1 of the first sensor transistor PT1.

The first gate layer GTL1 may be disposed on (e.g., disposed directly thereon) the first gate insulating layer GI1. The first gate layer GTL1 may include a gate electrode PGE1 of the first sensor transistor PT1.

The second active layer ACTL2 may be disposed on (e.g., disposed directly thereon) the first interlayer insulating layer ILD1. The second active layer ACTL2 may include an oxide-based material. In an embodiment, the second active layer ACTL2 may include a semiconductor region PACT2, a first electrode PDE2, and a second electrode PSE2 of the second sensor transistor PT2.

The third gate layer GTL3 may be disposed on (e.g., disposed directly thereon) the third gate insulating layer GI3. In an embodiment, the third gate layer GTL3 may include a gate electrode PGE2 of the second sensor transistor PT2. The gate electrode PGE2 of the second sensor transistor PT2 may be a portion of a reset signal line GRL.

The first source metal layer SDL1 may be disposed on (e.g., disposed directly thereon) the second interlayer insulating layer ILD2. In an embodiment, the first source metal layer SDL1 may include a sensor connection electrode PCE and a first sensor node electrode NSE1. The sensor connection electrode PCE may electrically connect the reset voltage line VRL and the second electrode PSE2 of the second sensor transistor PT2 to each other. The first sensor node electrode NSE1 may electrically connect the first electrode PDE2 of the second sensor transistor PT2 and the gate electrode PGE1 of the first sensor transistor PT1 to each other.

The second source metal layer SDL2 may be disposed on (e.g., disposed directly thereon) the first via layer VIA1. In an embodiment, the second source metal layer SDL2 may include the reset voltage line VRL and a second sensor node electrode NSE2. The second sensor node electrode NSE2 may electrically connect a sensor electrode PE and the first sensor node electrode NSE1 to each other.

The pixel defining film PDL may include a plurality of openings OPA. The plurality of openings OPA of the pixel defining film PDL may at least partially expose upper surfaces of the sensor electrodes PE of the light receiving elements PD. In some embodiments, the plurality of openings OPA may include light receiving openings OPA_P overlapping the sensor electrodes PE.

In an embodiment, the light receiving element PD may include the sensor electrode PE, a hole transporting layer HTL, a light receiving layer RCL, an electron transporting layer ETL, and a common electrode CAT. The sensor electrode PE may be disposed on (e.g., disposed directly thereon) the second via layer VIA2, and may be disposed at a same layer as the pixel electrode AE of the light emitting element ED. The sensor electrode PE may overlap (e.g., in a thickness direction of the optical transmitting/receiving panel 100) one of a plurality of light receiving areas PDA defined by the pixel defining film PDL.

The plurality of light receiving areas PDA may be areas defined by the light receiving openings OPA_P. For example, the plurality of light receiving areas PDA may be areas where the light receiving layers RCL overlap (e.g., in a thickness direction of the optical transmitting/receiving panel 100) the sensor electrodes PE within a plurality of light receiving openings OPA_P.

The hole transporting layer HTL may be disposed on (e.g., disposed directly thereon) the sensor electrode PE in the light receiving area PDA and may be disposed on (e.g., disposed directly thereon) the pixel defining film PDL in an area other than the light receiving area PDA. In an embodiment, the hole transporting layer HTL is not divided for each light receiving pixel OPD, and may be implemented as a common layer for all light emitting pixels SP and light receiving pixels OPD.

The light receiving layer RCL may be disposed on (e.g., disposed directly thereon) the hole transporting layer HTL. The light receiving layer RCL may receive light emitted from the emission area EA and reflected by the object. The light emitted from the light emitting element ED of the emission area EA may be reflected by the object, and the reflected light may arrive at the light receiving layer RCL. The light receiving element PD may convert energy of the light into an electrical signal (e.g., a current or a voltage) formed between the sensor electrode PE and the common electrode CAT, and the converted electrical signal may flow to the sensor node NS as a reverse bias current. For example, when the light receiving element PD receives the light and an electric field is formed between the sensor electrode PE of the light receiving element PD and the common electrode CAT, a current may flow in the light receiving element PD in proportion to an amount of the light.

The electron transporting layer ETL may be disposed on (e.g., disposed directly thereon) the light receiving layer RCL in the light receiving area PDA and may be disposed on (e.g., disposed directly thereon) the hole transporting layer HTL in the area other than the light receiving area PDA. In an embodiment, the electron transporting layer ETL is not divided for each light receiving pixel OPD, and may be implemented as a common layer for all light emitting pixels SP and light receiving pixels OPD.

The common electrode CAT may be disposed on (e.g., disposed directly thereon) the electron transporting layer ETL. For example, in an embodiment the common electrode CAT is not divided for each of the plurality of light receiving pixels OPD, and may be implemented in the form of an electrode common to all light emitting pixels SP and light receiving pixels OPD. The common electrode CAT may be a transparent electrode, and may transmit light. The common electrode CAT may be electrically connected to the low-potential line VSSL, and may receive a low-potential voltage, a common voltage, or a cathode voltage.

In some embodiments, when the light receiving layer RCL corresponds to an organic light receiving layer, a maximum peak wavelength of the light received by the light receiving layer RCL may be in a range of about 750 nm to about 840 nm. In an embodiment, when the light receiving layer RCL corresponds to a quantum dot light receiving layer, a maximum peak wavelength of the light received by the light receiving layer RCL may be in a range of about 850 nm to about 1450 nm. When the light receiving layer RCL corresponds to the quantum dot light receiving layer, the light receiving layer RCL may include a group III-V indium arsenide (InAs) compound.

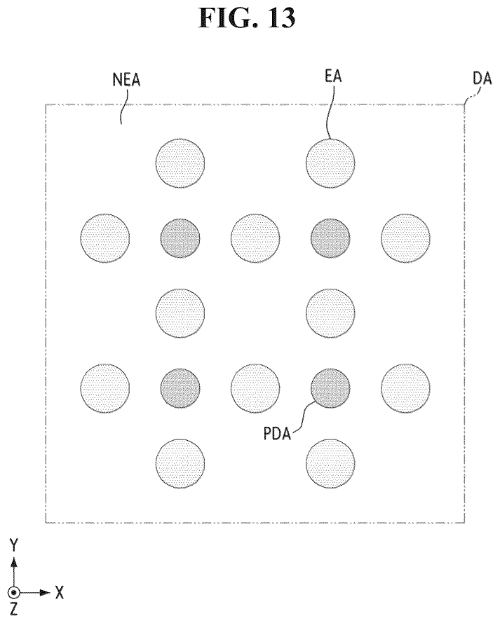

FIG. 13 is a plan view illustrating emission areas and light receiving areas of the optical transmitting/receiving device according to an embodiment.

Referring to FIG. 13, the sensing area DA may include emission areas EA and a non-emission area NEA. The emission areas EA may emit light of the light emitting elements ED, and the light emitting elements ED may not be disposed in the non-emission area NEA. The non-emission area NEA may include light receiving areas PDA spaced apart from each other with at least one emission area EA disposed between each of the light receiving areas PDA.

The emission areas EA may be spaced apart from each other in the X-axis direction and the Y-axis direction. In an embodiment, the emission areas EA may be disposed side by side along a diagonal direction defined by the X-axis direction and the Y-axis direction. In an embodiment, the emission areas EA may be disposed in a lattice shape. For example, the emission areas EA may be disposed in a diamond PenTile™ type. However, an arrangement of the emission areas EA (e.g., in a plan view) is not necessarily limited to that illustrated in FIG. 13.

The emission area EA may emit light of a specific wavelength. In some embodiments, the emission area EA may emit light of an infrared wavelength. For example, the emission area EA may emit light of a wavelength greater than or equal to about 700 nm.

For example, when the optical transmitting/receiving device 10 is used in the automobile, the emission area EA may continuously emit light while the automobile is being driven, but when the emission area EA emits visible light, the light emitted from the emission area EA may be viewed from the outside (e.g., the external environment), which may cause a safety problem. The optical transmitting/receiving device 10 according to an embodiment may prevent the light emitted from the emission area EA from being viewable from the outside (e.g., the external environment) by emitting the light of the infrared wavelength.

In addition, when the emission area EA emits the visible light, sensing accuracy may be reduced due to external visible light, but the optical transmitting/receiving device 10 according to an embodiment may increase the sensing accuracy by emitting the light of the infrared wavelength to minimize an influence of the external visible light.

The light receiving area PDA may be surrounded by the emission areas EA (e.g., in a plan view). The light receiving area PDA may be spaced apart from and disposed side by side with the emission areas EA in the X-axis direction and the Y-axis direction. The light receiving areas PDA may be spaced apart from each other, and at least one emission area EA may be disposed between the light receiving areas PDA. The light receiving area PDA may receive light emitted from the emission area EA and reflected by the object.

Areas (e.g., in a plan view) of the emission area EA and the light receiving area PDA may be different from each other. For example, an area (e.g., in a plan view) of the light receiving area PDA may be less than an area (e.g., in a plan view) of the emission area EA. The emission areas EA may have a greater area, such that a light emission rate may be increased, and the light receiving areas PDA may have a smaller area but be densely disposed, such that sensing accuracy may be increased.

It has been illustrated in FIG. 13 that four light receiving areas PDA are disposed between the emission areas EA, but the present disclosure is not necessarily limited thereto. Light receiving areas PDA less than or more than the four light receiving areas PDA may also be disposed between the emission areas EA.

It has been illustrated in FIG. 13 that each of the emission areas EA and the light receiving areas PDA has a circular shape in a plan view, but the present disclosure is not necessarily limited thereto. A shape of each of the emission areas EA and light receiving areas PDA may be changed into various shapes such as a polygonal shape, an elliptical shape, etc.

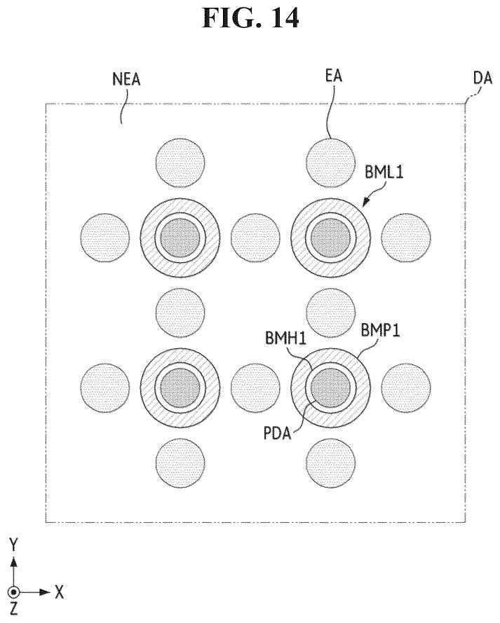

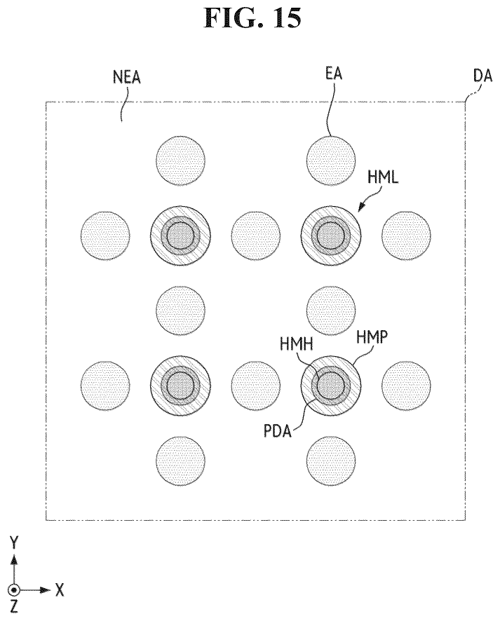

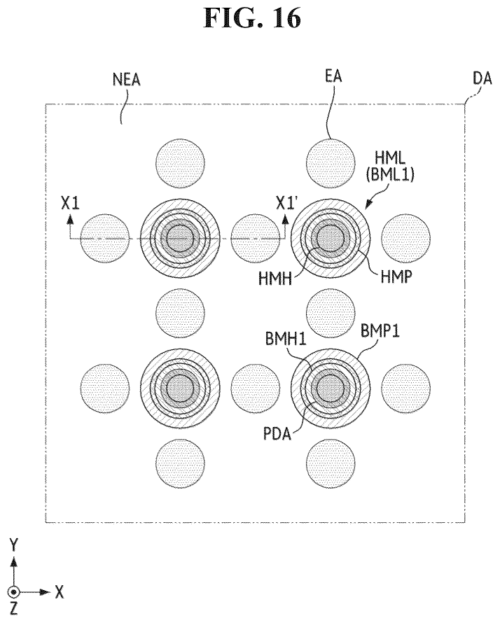

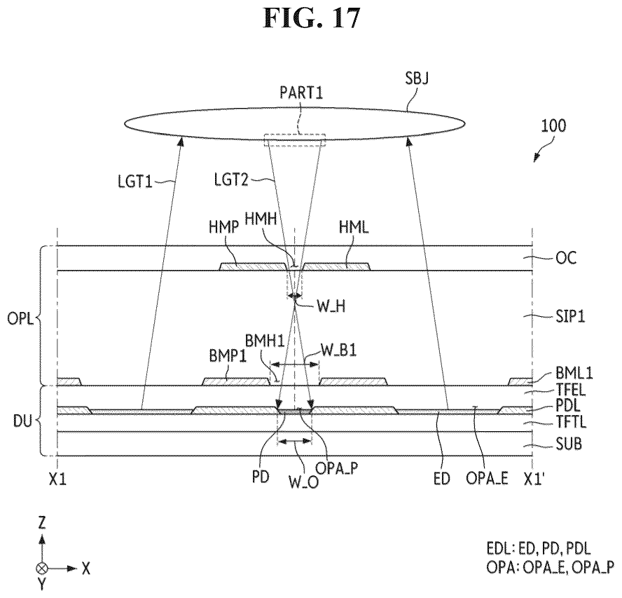

FIG. 14 is a plan view illustrating first light blocking layers disposed on the emission areas and the light receiving areas of the optical transmitting/receiving device according to an embodiment. FIG. 15 is a plan view illustrating light guide layers disposed on the emission areas and the light receiving areas of the optical transmitting/receiving device according to an embodiment in a first area. FIG. 16 is a plan view illustrating the first light blocking layers and the light guide layers disposed on the emission areas and the light receiving areas of the optical transmitting/receiving device according to an embodiment in the first area. FIG. 17 is a cross-sectional view taken along line X1-X1′ of FIG. 16.

Referring to FIGS. 14 to 17, the optical transmitting/receiving device 10 may include an optical layer OPL disposed on a sensor layer DU (e.g., disposed directly thereon in the Z-axis direction). In an embodiment, the optical layer OPL may include a first light blocking layer BML1, a first planarization layer SIP1, a light guide layer HML, and an overcoat layer OC (e.g., consecutively stacked in the Z-axis direction).

The first light blocking layer BML1 may be disposed on the sensor layer DU, for example, on the encapsulation layer TFEL (e.g., disposed directly thereon in the Z-axis direction). The first light blocking layer BML1 may include a light absorbing material. For example, in an embodiment the first light blocking layer BML1 may include an inorganic black pigment or an organic black pigment. The inorganic black pigment may be carbon black, and the organic black pigment may include at least one of Lactam Black, Perylene Black, and Aniline Black, but the present disclosure is not necessarily limited thereto.

The first planarization layer SIP1 may be disposed on (e.g., disposed directly thereon) the first light blocking layer BML1. In an embodiment, the first planarization layer SIP1 may be disposed over the entire surface of the sensing area DA and planarize an upper surface of the optical transmitting/receiving panel 100. For example, the first planarization layer SIP1 may be formed as one or more layers to planarize a step due to the first light blocking layer BML1. In an embodiment, the first planarization layer SIP1 may be a colorless light transmitting layer that does not have a color of a visible light band. For example, the first planarization layer SIP1 may include a colorless light transmitting organic material such as an acrylic resin, but is not necessarily limited thereto.

In some embodiments, a thickness of the first planarization layer SIP1 (e.g., a length of the first planarization layer SIP1 in the Z-axis direction) may be greater than a thickness (e.g., length in the Z-axis direction) of the encapsulation layer TFEL. Accordingly, a distance between the first light blocking layer BML1 and the light guide layer HML in the Z-axis direction may be greater than a distance between the first light blocking layer BML1 and the pixel defining film PDL in the Z-axis direction.

The light guide layer HML may be disposed on the first planarization layer SIP1 (e.g., disposed directly thereon in the Z-axis direction). The light guide layer HML may include a light absorbing material. For example, in an embodiment the light guide layer HML may include an inorganic black pigment or an organic black pigment. The inorganic black pigment may be carbon black, and the organic black pigment may include at least one of Lactam Black, Perylene Black, and Aniline Black, but the present disclosure is not necessarily limited thereto. In an embodiment, the light guide layer HML may include a metal material capable of reflecting light of an infrared wavelength.

The overcoat layer OC may be disposed on (e.g., disposed directly thereon) the light guide layer HML. In an embodiment, the overcoat layer OC may be disposed over the entire surface of the sensing area DA and planarize the upper surface of the optical transmitting/receiving panel 100. For example, the overcoat layer OC may be formed as one or more layer to planarize a step due to the light guide layer HML. In an embodiment, the overcoat layer OC may be a colorless light transmitting layer that does not have a color of a visible light band. For example, the overcoat layer OC may include a colorless light transmitting organic material such as an acrylic resin, but is not necessarily limited thereto.

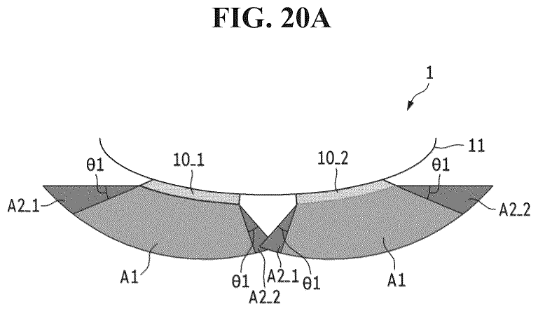

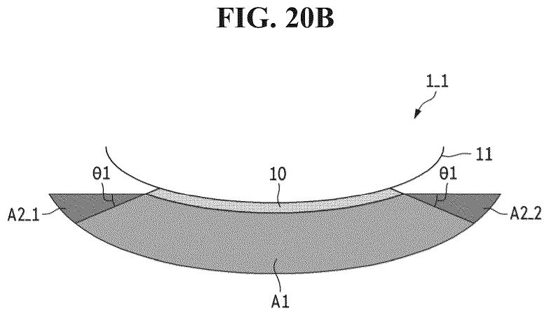

Hereinafter, a first light blocking pattern BMP1 disposed at the first light blocking layer BML1 and a light guide pattern HMP disposed at the light guide layer HML in a first area A1 (see FIG. 20A) will be described.

The first light blocking layer BML1 may include a plurality of first light blocking patterns BMP1. The plurality of first blocking patterns BMP1 may include a plurality of first transmission holes BMH1, respectively. For example, in an embodiment the first blocking pattern BMP1 may have a ring shape or a doughnut shape in a plan view by including the first transmission hole BMH1 located approximately at the center.

It has been illustrated in FIG. 14 that the first blocking pattern BMP1 has an approximately circular shape in a plan view, but the present disclosure is not necessarily limited thereto. A shape of the first blocking pattern BMP1 may correspond to a shape of the light receiving area PDA in a plan view, and may be, for example, an elliptical shape, other polygonal shapes, etc.

The plurality of first blocking patterns BMP1 may be disposed on the light receiving areas PDA, respectively. For example, in an embodiment the plurality of first transmission holes BMH1 may overlap the plurality of light receiving areas PDA, respectively, and may not overlap the plurality of emission areas EA.

As illustrated in an embodiment shown in FIG. 14, in the first area A1 (see FIG. 20A), the first blocking pattern BMP1 may surround (e.g., completely surround) the light receiving area PDA in plan view. The first blocking pattern BMP1 may be disposed on the light receiving area PDA, but the first transmission hole BMH1 may overlap the light receiving area PDA, such that a body itself of the first blocking pattern BMP1 may not overlap the light receiving area PDA in the Z-axis direction.

For example, in the first area A1 (see FIG. 20A), an inner side of the first blocking pattern BMP1 may be spaced apart from a boundary of the light receiving area PDA in a plan view. For example, as illustrated in FIG. 17, the inner side of the first blocking pattern BMP1 may be disposed outside a boundary of the light receiving opening OPA_P of the pixel defining film PDL. For example, a width W_B1 of the first transmission hole BMH1 (e.g., in a horizontal direction, such as the X-axis direction) may be greater than a width W_O of the light receiving opening OPA_P of the pixel defining film PDL (e.g., in a horizontal direction, such as the X-axis direction). In a plan view, a size of the first transmission hole BMH1 may be greater than a size of the light receiving opening OPA_P of the pixel defining film PDL.

The light guide layer HML may include a plurality of light guide patterns HMP. The plurality of light guide patterns HMP may include a plurality of light guide holes HMH, respectively. For example, in an embodiment the light guide pattern HMP may have a ring shape or a doughnut shape in a plan view by including the light guide hole HMH located approximately at the center.

It has been illustrated in FIG. 15 that the light guide pattern HMP has an approximately circular shape in a plan view, but the present disclosure is not necessarily limited thereto. A shape of the light guide pattern HMP may correspond to the shape of the light receiving area PDA in a plan view, and may be, for example, an elliptical shape, other polygonal shapes, etc. in some embodiments.

The plurality of light guide patterns HMP may be disposed on the light receiving areas PDA, respectively. For example, the plurality of light guide holes HMH may overlap (e.g., in the Z-axis direction) the plurality of light receiving areas PDA, respectively, and may not overlap (e.g., in the Z-axis direction) the plurality of emission areas EA.

As illustrated in FIG. 15, in the first area A1 (see FIG. 20A), the light guide pattern HMP may surround (e.g., completely surround) the light receiving area PDA in a plan view. For example, an outer side of the light guide pattern HMP may surround the light receiving area PDA in plan view. The light guide hole HMH may overlap (e.g., in the Z-axis direction) the light receiving area PDA. An inner side of the light guide pattern HMP may be surrounded by the boundary of the light receiving area PDA in plan view. For example, the inner side of the light guide pattern HMP may be surrounded by the boundary of the light receiving opening OPA_P of the pixel defining film PDL in a plan view. Accordingly, a body itself of the light guide pattern HMP may at least partially overlap the light receiving area PDA in the Z-axis direction.

For example, in the first area A1 (see FIG. 20A), in a plan view, the inner side of the light guide pattern HMP may be located inside the boundary of the light receiving area PDA, and the outer side of the light guide pattern HMP may be located outside the boundary of the light receiving area PDA. For example, as illustrated in FIG. 17, the inner side of the light guide pattern HMP may be located inside the boundary of the light receiving opening OPA_P of the pixel defining film PDL, and the outer side of the light guide pattern HMP may be located outside the boundary of the light receiving opening OPA_P of the pixel defining film PDL. For example, a width W_H (e.g., length in a horizontal direction, such as the X-axis direction) of the light guide hole HMH may be less than the width W_O (e.g., length in a horizontal direction, such as the X-axis direction) of the light receiving opening OPA_P of the pixel defining film PDL. In a plan view, a size of the light guide hole HMH may be less than the size of the light receiving opening OPA_P of the pixel defining film PDL overlapping the light receiving area PDA.

In the first area A1 (see FIG. 20A), as illustrated in FIGS. 16 and 17, the light guide hole HMH may overlap the first transmission hole BMH1 (e.g., in the Z-axis direction). For example, in an embodiment the first transmission hole BMH1 may completely overlap the light guide hole HMH (e.g., in a plan view). The width W_H (e.g., length in a horizontal direction, such as the X-axis direction) of the light guide hole HMH may be less than the width W_B1 (e.g., length in a horizontal direction, such as the X-axis direction) of the first transmission hole BMH1. In a plan view, the size of the light guide hole HMH may be less than the size of the first transmission hole BMH1. In some embodiments, an area of the light guide hole HMH (e.g., in a plan view) may be less than an area of the first transmission hole BMH1 (e.g., in a plan view). The inner side of the light guide pattern HMP may be located inside an inner side of the first blocking pattern BMP1, and the outer side of the light guide pattern HMP may be located inside an outer side of the first blocking pattern BMP1. The outer side of the light guide pattern HMP may be located between the outer side of the first blocking pattern BMP1 and the inner side of the first blocking pattern BMP1 (e.g., in a plan view).

In the optical transmitting/receiving device 10 according to an embodiment of the present disclosure, first light LGT1 emitted from the light emitting element ED may be reflected by an object SBJ. Second light LGT2 reflected by the object SBJ may be incident on the light receiving element PD through the light guide hole HMH and the first transmission hole BMH1.

When the second light LGT2 passes through a narrow hole or slit such as the light guide hole HMH, a diffraction phenomenon may occur. For example, some of light that should be reflected or absorbed and blocked by the light guide pattern HMP may pass through the light guide hole HMH and then arrive at the light receiving element PD. The optical layer OPL may limit a path of light incident on the light receiving element PD to a path through the first transmission hole BMH1 by including the first light blocking layer BML1. For example, the first light blocking layer BML1 of the optical layer OPL may suppress and block diffraction of the reflected light. Accordingly, quality and accuracy of the sensing data of the optical transmitting/receiving device 10 may be increased.

The optical transmitting/receiving device 10 according to an embodiment of the present disclosure may increase the accuracy of the sensing data by including the light guide layer HML. For example, a sensing range of an individual light receiving element PD may be narrowed through the light guide hole HMH having a relatively small width (or size, such as area in a plan view). For example, the sensing range of the individual light receiving element PD may be a first part PART1 of the object SBJ disposed side by side with the light receiving element PD and the light guide hole HMH. Since only light reflected by the first part PART1 may be incident on the light receiving element PD, accuracy of sensing data of the light receiving element PD may be increased.

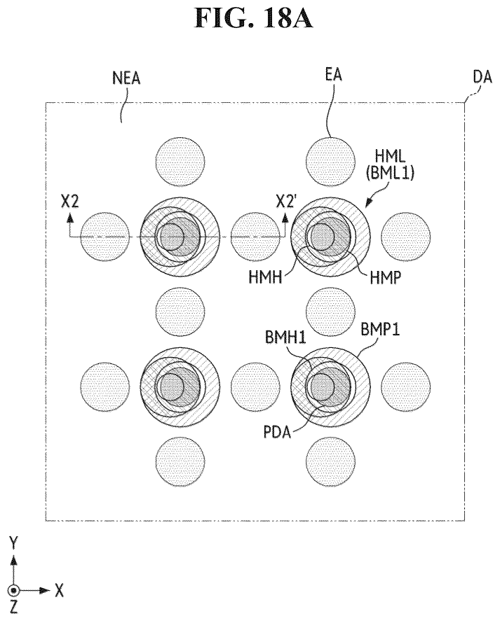

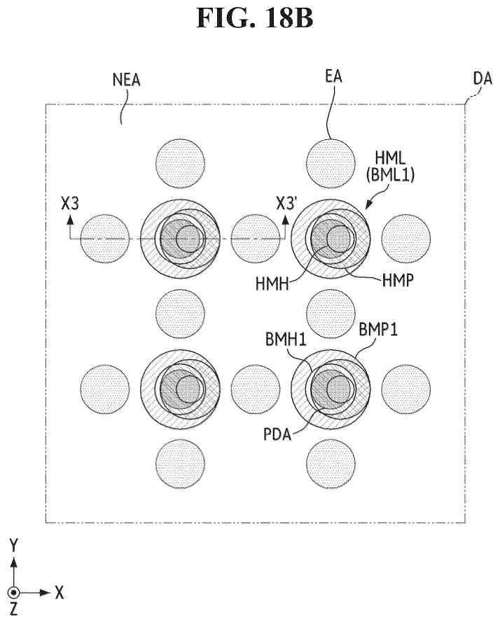

Depending on a disposition of the light guide hole HMH, a sensing range of the optical transmitting/receiving device 10 may be widened or the optical transmitting/receiving device 10 may be designed to sense a specific area. This will be described with reference to FIG. 18A and the like.

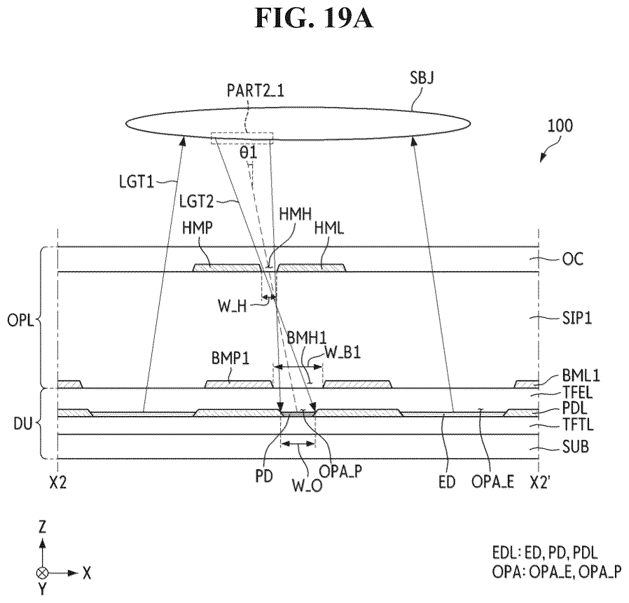

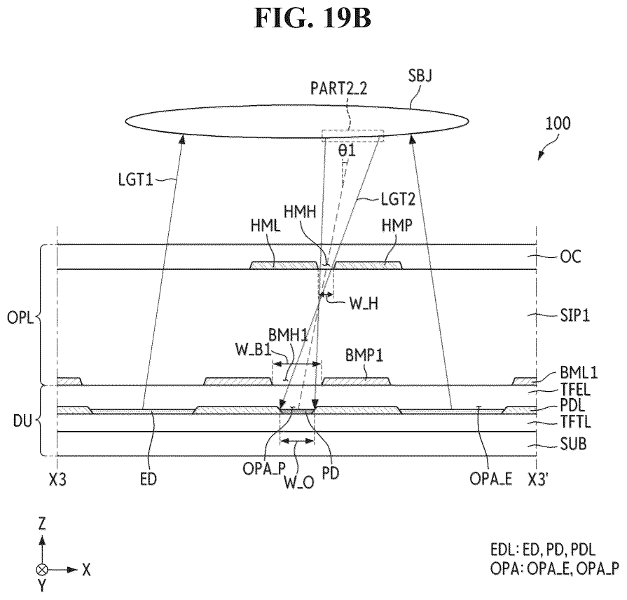

FIG. 18A is a plan view illustrating first light blocking layers and light guide layers disposed on the emission areas and the light receiving areas of the optical transmitting/receiving device according to an embodiment in a second-first area. FIG. 18B is a plan view illustrating first light blocking layers and light guide layers disposed on the emission areas and the light receiving areas of the optical transmitting/receiving device according to an embodiment in a second-second area. FIG. 19A is a cross-sectional view taken along line X2-X2′ of FIG. 18A. FIG. 19B is a cross-sectional view taken along line X3-X3′ of FIG. 18B. FIG. 20A is a schematic view illustrating a sensing range of the optical transmitting/receiving device according to an embodiment of FIG. 1. FIG. 20B is a schematic view illustrating a sensing range of the optical transmitting/receiving device according to an embodiment of FIG. 3.

Referring to FIGS. 18A to 20B in addition to FIGS. 16 and 17, a location of the optical guide pattern HMP of the optical transmitting/receiving device 10 in a second area A2_1 and A2_2 (see FIG. 20A) is different from a location of the optical guide pattern HMP of the optical transmitting/receiving device 10 in the first area A1 (see FIG. 20A) described with reference to FIG. 16 and the like.

In an embodiment, in the second area A2_1 and A2_2 (see FIG. 20A), the light guide pattern HMP of the optical transmitting/receiving device 10 may be shifted (e.g., not aligned) in a horizontal direction (e.g., one direction in the X-axis direction and/or the Y-axis direction) with respect to the first light blocking pattern BMP1 and the light receiving element PD. For example, the light guide hole HMH may be shifted (e.g., not aligned) in the horizontal direction (e.g., in the X-axis direction and/or the Y-axis direction) with respect to the first transmission hole BMH1 and the light receiving element PD. Thus, a center of the shifted light guide hole HMH in a plan view may not be aligned with centers of the first transmission hole BMH1 and the light receiving element PD and may be offset from the centers of the first transmission hole BMH1 and the light receiving element PD in a horizontal direction.

As an example, as illustrated in embodiments shown in FIGS. 18A and 19A, a central portion of the light guide pattern HMP may be shifted (e.g., not aligned) in a direction opposite to the X-axis direction with respect to a central portion of the first light blocking pattern BMP1 and a central portion of the light receiving element PD.

As another example, as illustrated in embodiments shown in FIGS. 18B and 19B, a central portion of the light guide pattern HMP may be shifted (e.g., not aligned) in the X-axis direction with respect to a central portion of the first light blocking pattern BMP1 and a central portion of the light receiving element PD.

However, embodiments of the present disclosure are not necessarily limited thereto, and the light guide pattern HMP may be shifted in the X-axis direction, the Y-axis direction, a direction opposite to the Y-axis direction, a diagonal direction defined by the X-axis direction and the Y-axis direction, and the like.

A portion of the body of the light guide pattern HMP may at least partially overlap the first transmission hole BMH1 and the light receiving element PD in the Z-axis direction (e.g., in a plan view). As illustrated in FIGS. 18A and 18B, the light guide hole HMH may still overlap the light receiving area PDA in the Z-axis direction. However, depending on a degree to which the light guide pattern HMP is shifted, as illustrated in FIGS. 19A and 19B, the light guide hole HMH may not overlap the light receiving element PD in the Z-axis direction. For example, the light guide hole HMH may only partially overlap the light receiving area PDA in the plan view or may not overlap the light receiving area PDA in the plan view.

In some embodiments, an area (e.g., an overlap area) where the light receiving opening OPA_P of the pixel defining film PDL and the light guide hole HMH overlap each other in a plan view in the first area A1 described with reference to FIG. 16 and the like may be greater than an area (e.g., an overlap area) where the light receiving opening OPA_P of the pixel defining film PDL and the light guide hole HMH overlap each other in plan view in the second area A2_1 and A2_2 described with reference to FIGS. 18A and 18B.

Depending on a direction in which the light guide pattern HMP is shifted, a path through which the second light LGT2 reflected by the object SBJ is incident on the light receiving element PD may be changed. For example, as illustrated in embodiments shown in FIGS. 19A and 19B, as the light guide pattern HMP is shifted, the path through which the second light LGT2 is incident on the light receiving element PD may be inclined by a first angle θ1. Accordingly, the sensing range of the light receiving element PD may be a second part PART2_1 or PART2_2 of the object SBJ disposed side by side with the light receiving element PD and the light guide hole HMH.

As an example, as illustrated in FIG. 19A, when the light guide pattern HMP is shifted in the direction opposite to the X-axis direction, the sensing range of the light receiving element PD may be a second-first part PART2_1 of the object SBJ disposed side by side with the light receiving element PD and the light guide hole HMH.

As another example, as illustrated in FIG. 19B, when the light guide pattern HMP is shifted in the X-axis direction, the sensing range of the light receiving element PD may be a second-second part PART2_2 of the object SBJ disposed side by side with the light receiving element PD and the light guide hole HMH.

For example, the optical transmitting/receiving device 10 according to an embodiment may have a sensing range different from the first part PART1 (see FIG. 17), which is the sensing range of the optical transmitting/receiving device 10 according to an embodiment described with reference to FIG. 17 and the like. As described above, the optical transmitting/receiving device 10 may be designed to sense a specific area depending on a disposition of the light guide hole HMH.

Within the sensing area DA of the optical transmitting/receiving device 10, the optical layer OPL described with reference to FIG. 16 and the like may be disposed on some light receiving areas PDA, and the optical layer OPL described with reference to FIGS. 18A and 18B and the like may be disposed on the other light receiving areas PDA.

As an example, as illustrated in FIG. 20A, when the optical transmitting/receiving devices 10_1 and 10_2 are applied to the electronic device 1, the optical layers OPL described with reference to FIGS. 18A and 18B and the like may be mainly located adjacent to opposite ends of the optical transmitting/receiving devices 10_1 and 10_2 to widen sensing ranges of the optical transmitting/receiving devices 10_1 and 10_2. As described above, depending on the disposition of the light guide hole HMH, the sensing ranges of the optical transmitting/receiving devices 10_1 and 10_2 may be widened.

First areas A1 illustrated in FIG. 20A represent the sensing ranges of the optical transmitting/receiving devices 10_1 and 10_2 when the optical layer OPL described with reference to FIG. 16 and the like is disposed. A second-first area A2_1 illustrated in FIG. 20A represents a sensing range widened by the first angle θ1 when the optical layer OPL described with reference to FIG. 18A and the like is located adjacent to a left end of each of the optical transmitting/receiving devices 10_1 and 10_2. A second-second area A2_2 illustrated in FIG. 20A represents a sensing range widened by the first angle θ1 when the optical layer OPL described with reference to FIG. 18B and the like is located adjacent to a right end of each of the optical transmitting/receiving devices 10_1 and 10_2.

As another example, as illustrated in FIG. 20B, when the optical transmitting/receiving device 10 is applied to the electronic device 1, the optical layers OPL described with reference to FIGS. 18A and 18B and the like may be mainly located adjacent to opposite ends of the optical transmitting/receiving device 10 in order to widen a sensing range of the optical transmitting/receiving device 10. As described above, depending on the disposition of the light guide hole HMH, the sensing range of the optical transmitting/receiving device 10 may be widened.

A first area A1 illustrated in FIG. 20B represents the sensing range of the optical transmitting/receiving device 10 when the optical layer OPL described with reference to FIG. 16 and the like is disposed. A second-first area A2_1 illustrated in FIG. 20B represents a sensing range widened by the first angle θ1 when the optical layer OPL described with reference to FIG. 18A and the like is located adjacent to a left end of the optical transmitting/receiving device 10. A second-second area A2_2 illustrated in FIG. 20B represents a sensing range widened by the first angle θ1 when the optical layer OPL described with reference to FIG. 18B and the like is located adjacent to a right end of the optical transmitting/receiving device 10.

When the optical layer OPL described with reference to FIGS. 18A and 18B and the like is disposed on the light receiving area PDA sensing the first area A1 as well as when the optical layers OPL are located adjacent to opposite ends of the optical transmitting/receiving device 10, quality and accuracy of the sensing data of the optical transmitting/receiving device 10 may be increased.

Hereinafter, embodiments of the optical transmitting/receiving device 10 according to an embodiment will be described. In the following embodiments, same components as those of the above-described embodiment will be denoted by same reference numerals, and an overlapping description thereof will be omitted or simplified and contents different from those described above will be mainly described for economy of explanation.

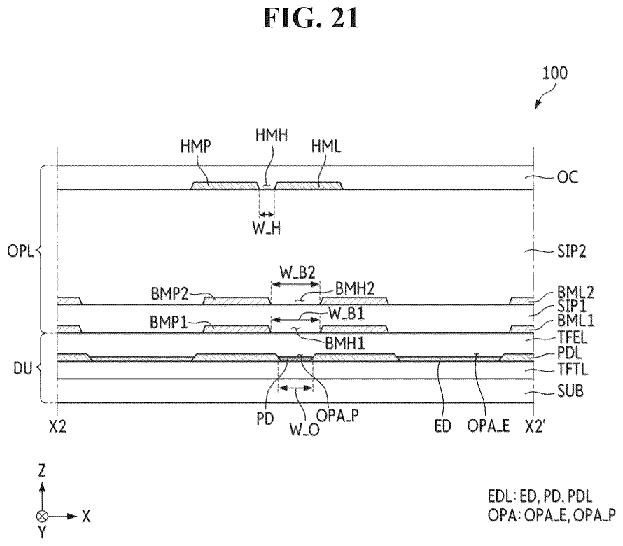

FIG. 21 is a cross-sectional view illustrating an optical transmitting/receiving device according to an embodiment.

Referring to FIG. 21, an optical transmitting/receiving device 10 according to an embodiment is different from the optical transmitting/receiving device 10 according to embodiments described above with reference to FIGS. 17 and 19A and the like in that it further includes a second light blocking layer BML2 and a second planarization layer SIP2.

For example, the optical layer OPL of the optical transmitting/receiving device 10 may further include a second light blocking layer BML2 and a second planarization layer SIP2.

The second light blocking layer BML2 may be disposed on the first planarization layer SIP1 (e.g., disposed directly thereon in the Z-axis direction). The second light blocking layer BML2 may be disposed between the first light blocking layer BML1 and the light guide layer HML (e.g., in a thickness direction of the optical transmitting/receiving panel 100, such as the Z-axis direction). The second light blocking layer BML2 may include a light absorbing material. For example, in an embodiment the second light blocking layer BML2 may include an inorganic black pigment or an organic black pigment. In an embodiment, the inorganic black pigment may be carbon black, and the organic black pigment may include at least one of Lactam Black, Perylene Black, and Aniline Black, but the present disclosure is not necessarily limited thereto.

The second light blocking layer BML2 may include a plurality of second light blocking patterns BMP2. The plurality of second light blocking patterns BMP2 may include a plurality of second transmission holes BMH2, respectively. For example, in an embodiment the second blocking pattern BMP2 may have a ring shape or a doughnut shape in a plan view by including the second transmission hole BMH2 located approximately at the center.

A shape of the second light blocking pattern BMP2 is not necessarily limited to a circular shape. The shape of the second blocking pattern BMP2 may correspond to the shape of the light receiving area PDA in a plan view, and may be, for example, an elliptical shape, other polygonal shapes, etc. in some embodiments.

The plurality of second blocking patterns BMP2 may be disposed on the light receiving areas PDA, respectively. For example, the plurality of second transmission holes BMH2 may overlap (e.g., in the Z-axis direction) the plurality of light receiving areas PDA, respectively, and may not overlap (e.g., in the Z-axis direction) the plurality of emission areas EA.

In an embodiment, the second light blocking pattern BMP2 may surround (e.g., completely surround) the light receiving area PDA in a plan view. The second blocking pattern BMP2 may be disposed on the light receiving area PDA, but the second transmission hole BMH2 may overlap (e.g., in the Z-axis direction) the light receiving area PDA, such that a body itself of the second blocking pattern BMP2 may not overlap the light receiving area PDA in the Z-axis direction.

For example, an inner side of the second light blocking pattern BMP2 may be spaced apart from the boundary of the light receiving area PDA in a plan view. For example, as illustrated in FIG. 21, the inner side of the second blocking pattern BMP2 may be disposed outside the boundary of the light receiving opening OPA_P of the pixel defining film PDL. For example, a width W_B2 (e.g., length in a horizontal direction, such as the X-axis direction) of the second transmission hole BMH2 may be greater than the width W_O (e.g., length in a horizontal direction, such as the X-axis direction) of the light receiving opening OPA_P of the pixel defining film PDL. In plan view, a size (e.g., area in a plan view) of the second transmission hole BMH2 may be greater than the size (e.g., area in a plan view) of the light receiving opening OPA_P of the pixel defining film PDL. The size of a hole in a plan view may mean a width of the hole in a horizontal direction and/or an area of the hole in a plan view.

The width W_B2 (e.g., length in a horizontal direction, such as the X-axis direction) of the second transmission hole BMH2 may be greater than the width W_H (e.g., length in a horizontal direction, such as the X-axis direction) of the light guide hole HMH. The size (e.g., area in a plan view) of the second transmission hole BMH2 may be greater than the size (e.g., area in a plan view) of the light guide hole HMH. In some embodiments, the width W_B2 (e.g., length in a horizontal direction, such as the X-axis direction) of the second transmission hole BMH2 may be the same as the width W_B1 (e.g., length in a horizontal direction, such as the X-axis direction) of the first transmission hole BMH1. However, embodiments of the present disclosure are not necessarily limited thereto, and the width W_B2 (e.g., length in a horizontal direction, such as the X-axis direction) of the second transmission hole BMH2 may also be different from the width W_B1 (e.g., length in a horizontal direction, such as the X-axis direction) of the first transmission hole BMH1. The size (e.g., area in a plan view) of the second transmission hole BMH2 may be the same as the size (e.g., area in a plan view) of the first transmission hole BMH1. However, embodiments of the present disclosure are not necessarily limited thereto, and the size of the second transmission hole BMH2 may also be different from the size of the first transmission hole BMH1.

It has been illustrated in FIG. 21 that the optical layer OPL includes two light blocking layers such as the first light blocking layer BML1 and the second light blocking layer BML2, but the present disclosure is not necessarily limited thereto. For example, the optical layer OPL may also include three or more light blocking layers disposed on different layers from each other in some embodiments.

When light passes through a narrow hole or slit such as the light guide hole HMH, a diffraction phenomenon may occur. For example, some of light that should be reflected or absorbed and blocked by the light guide pattern HMP may pass through the light guide hole HMH and then arrive at the light receiving element PD. The optical layer OPL may limit a path of light incident on the light receiving element PD to a path through the first transmission hole BMH1 and the second transmission hole BMH2 by further including the second light blocking layer BML2. For example, the light blocking layers of the optical layer OPL may suppress and block diffraction of the reflected light. Accordingly, quality and accuracy of the sensing data of the optical transmitting/receiving device 10 may be increased.

The second planarization layer SIP2 may be disposed on (e.g., disposed directly thereon) the second light blocking layer BML2. The second planarization layer SIP2 may be disposed between the second light blocking layer BML2 and the light guide layer HML (e.g., in the Z-axis direction). In an embodiment, the second planarization layer SIP2 may be disposed over the entire surface of the sensing area DA and planarize an upper surface of the optical transmitting/receiving panel 100. For example, the second planarization layer SIP2 may be formed as one or more layers to planarize a step due to the second light blocking layer BML2. In an embodiment, the second planarization layer SIP2 may be a colorless light transmitting layer that does not have a color of a visible light band. For example, the second planarization layer SIP2 may include a colorless light transmitting organic material such as an acrylic resin, but is not necessarily limited thereto.

### The Electronic Device

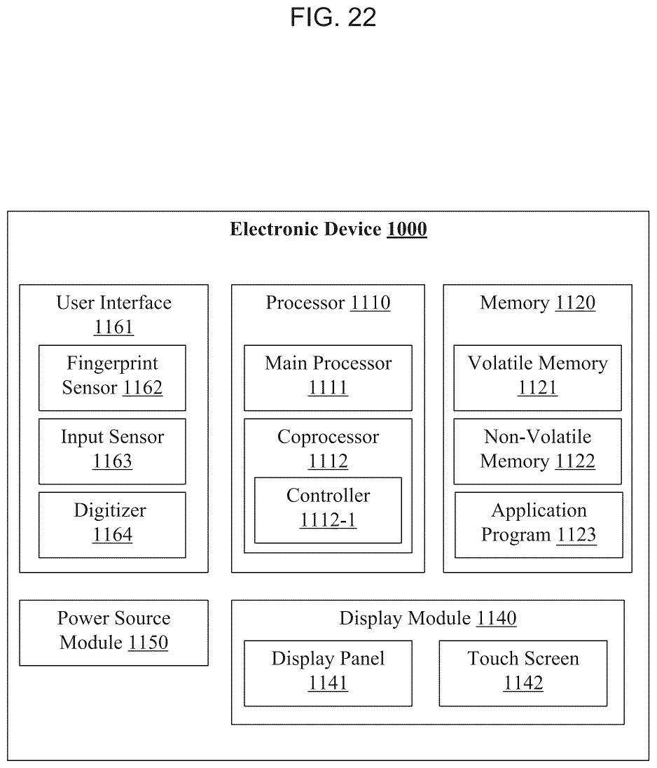

FIG. 22 is a diagram illustrating an electronic device according to an embodiment of the present invention. Referring to FIG. 22, the electronic device 1000 according to one embodiment of the present invention may output various information (e.g., images, text, music, etc.) through a display module 1140, which, for example, may correspond to the optical transmitting/receiving panel 100 and/or the optical transmitting/receiving devices 10_1 and 10_2. When a processor 1110 executes an application stored in a memory 1120, the display module 1140 may provide application information to a user through a display panel 1141.

In some embodiments, the electronic device 1000 may be configured as a smartphone, camera, smart TV, monitor, smartwatch, tablet, automotive display, or AR/VR headset. For example, the electronic device 1000 may be a smartphone including a touch-sensitive display area DA for interaction and a non-display area NDA including sensors and circuits for enhanced functionality. For example, the electronic device 1000 may be a television or monitor including a large display area DA for high-resolution video playback and a non-display area NDA incorporating driving circuits or connectivity modules for external inputs. For example, the electronic device 1000 may be a smartwatch including a display area DA optimized for compact and high-clarity visuals and a non-display area NDA integrating biometric sensors for health monitoring. In some cases, the electronic device 1000 be an AR/VR headset.

In some embodiments, memory 1120 may store information such as software codes for operating an application program 1123. The application program 1123 may include a software designed to execute specific tasks or provide functionality to a user. The application program 1123 may operate under the control of the processor 1110 and utilizes data stored in the memory 1120 to deliver a wide range of features, such as productivity tools, multimedia streaming and playback, file or mail deliveries or communication services. The application program 1123 interacts seamlessly with the user interface 1161 or touch screen 1142, allowing a user to launch, navigate, and utilize the program through user inputs such as touch, tap, gesture, or voice interaction.

Upon user selection of an application via touch screen 1142 or user interface 1161, the processor 1110 may execute the application program 1123 corresponding to the selected application retrieved from the memory 1120 to perform functionalities of the application. For example, when a user selects a camera application by tapping the icon (or a camera application icon) presented on the display panel 1141, the processor 1110 activates a camera module. The processor 1110 may transmit image data corresponding to a captured image acquired through the camera module to the display module 1140. The display module 1140 may display an image corresponding to the captured image through the display panel 1141.

As another example, when a user wishes to make a phone call, the user taps the telephone icon displayed on the display module 1140, the processor 1110 may execute a phone application program stored in the memory 1120. A telephone keypad may be presented on the display panel 1141 for the user to enter a phone number to call.

As another example, the display module 1140 may be integrated into an electronic device 1000, such as a laptop computer, smart TV, or tablet. A user wishing to access a multimedia streaming application (e.g., to watch a music video or movie) can do so by tapping the corresponding icon. This action activates the application, allowing the user to view the streamed content.

The processor 1110 may include a main processor 1111 and an auxiliary or coprocessor 1112. The main processor 1111 may include a central processing unit (CPU). The main processor 1111 may further include one or more of a graphics processing unit (GPU), a communication processor (CP), and an image signal processor (ISP).

The coprocessor 1112 may include a controller 1112-1. The controller 1112-1 may include an interface conversion circuit and a timing control circuit. The controller 1112-1 may receive an image signal from the main processor 1111, convert the data format of the image signal to match the interface specifications with the display module 1140, and output image data. The controller 1112-1 may output various control signals to drive the display module 1140. For example, the controller 1112-1 may drive the display module 1140 to display the icon on the display screen suitable for selection by a user to cause execution of an application program 1123.

The memory 1120 may store one or more application programs 1123 and various data used by at least one component (for example, the processor 1110 or the user interface 1161) of the electronic device 1000 and input data or output data for commands related thereto. For example, a camera application program, a GPS application program, an augmented reality and virtual reality application program, and other application programs that can be executed by the processor 1110 upon selection of corresponding icons presented on the display screen (or display panel 1141) via the touch screen 1142 or user interface 1161 by the user. In addition, various setting data corresponding to user settings may be stored in the memory 1120. The memory 1120 may include volatile memory 1121 and non-volatile memory 1122.

The display module 1140 may output visual information (images) to the user. The display module 1140 may include the display panel 1141, a gate driver, the source driver, a voltage generation circuit, and a touch screen 1142. The display module 1140 may further include a window, a chassis, and a bracket to protect the display panel 1141. The display module 1140 may include at least a part of the configuration of the optical transmitting/receiving panel 100 and/or the optical transmitting/receiving devices 10_1 and 10_2.

The user interface 1161 serves as the interaction medium between a user and the electronic device 1000. The user interface 1161 may detect an input by a part (e.g., finger) of a user's body or an input by a pen or a mouse, and generate an electric signal or data value corresponding to the input. The user interface 1161 includes the fingerprint sensor 1162, the input sensor 1163, and a digitizer 1164.

The fingerprint sensor 1162 may sense a fingerprint for biometric recognition of the user and may also measure one or more biological signals such as blood pressure, moisture, or body mass.

The input sensor 1163 may sense user interactions including touch, tap, gesture, motion, spoken command, and eye movement. The input sensor 1163 includes optical sensors for image capture, eye tracking, or motion and gesture detection. Optical sensors may be infrared or semiconductor photodetectors. The input sensor 1163 includes audio and acoustic sensors, which may be MEMS microphones for voice recognition or sound-based interaction. The audio and acoustic sensors can be installed as part of the user interface 1161 or embedded in the display panel 1141.

The digitizer 1164 may generate a data value corresponding to coordinate information of input by a pen or a mouse to control movement of an onscreen cursor. The digitizer 1164 may generate the amount of change in electromagnetic due to the input as the data value. The digitizer may detect an input by a passive pen or transmit and receive data with an active pen or a remote.

At least one of the fingerprint sensor 1162, the input sensor 1163, or the digitizer 1164 may be implemented as a sensor layer formed on the top layer of the display panel 1141 through a continuous process with a process of forming elements (for example, the light emitting element, the transistor, and the like) included in the display panel 1141.

In addition, the user interface 1161 may further include, for example, a gesture sensor, a gyro sensor that senses rotational movements, an acceleration sensor to track translational movement, a grip sensor, a pressure sensor, a proximity sensor, a color sensor, an infrared (IR) emitter and camera sensor for tracking gaze direction and eye movements, a temperature sensor, or a light sensor. For example, the gyro sensor, acceleration sensor, and infrared emitter and camera may be particularly suitable for AR/VR headset functions.

The touch screen 1142 includes touch sensors embedded in semiconductor layers of the display panel 1141 to sense pressure applied to the top layer (screen) of the display panel 1141. The touch sensors can be a capacitive or a resistive type. The touch screen 1142 may serve as the primary interface for the user to select and navigate applications, control, and interact with the electronic device 1000.

The display panel 1141 (or display) may include a liquid crystal display panel, an organic light emitting display panel, or an inorganic light emitting display panel, and the type of the display panel 1141 is not particularly limited. The display panel 1141 may be of a rigid type or a flexible type that can be rolled or folded. The display module 1140 may further include a supporter, bracket, heat dissipation member, and the like that support the display panel 1141. The display panel 1141 may include the optical transmitting/receiving panel 100 and/or the optical transmitting/receiving devices 10_1 and 10_2.

The power source module 1150 may supply power to the components of the electronic device 1000. The power source module 1150 may include a battery that charges the power source voltage. The battery may include a non-rechargeable primary battery or a rechargeable secondary battery or fuel cell. The power source module 1150 may include a power management integrated circuit (PMIC). The PMIC may supply optimized power source to each of the components described above including the display module 1140.

In concluding the detailed description, those skilled in the art will appreciate that many variations and modifications can be made to the described embodiments without substantially departing from the principles of the present disclosure. Therefore, the described embodiments of the present disclosure are used in a generic and descriptive sense only and not for purposes of limitation.

What is claimed is:

1. A light receiving device comprising:
a substrate including a first area and a second area;
an element layer disposed on the substrate, the element layer including a pixel defining film including a first opening disposed in the first area and a second opening disposed in the second area and a first light receiving area and a second light receiving area respectively defined by the first opening and the second opening; and
an optical layer disposed on the element layer, the optical layer including a first light blocking layer and a light guide layer disposed on the first light blocking layer,
wherein the first light blocking layer includes a plurality of first light blocking patterns respectively including a plurality of first transmission holes,
the light guide layer includes a first light guide pattern including a first light guide hole corresponding to the first opening and a second light guide pattern including a second light guide hole corresponding to the second opening, and
the first light guide hole overlaps the first opening in a plan view, and the second light guide hole is shifted in one direction with respect to the second opening in the plan view.

2. The light receiving device of claim 1, wherein:
the first light guide hole completely overlaps the first light receiving area in the plan view; and
the second light guide hole only partially overlaps or does not overlap the second light receiving area in the plan view.

3. The light receiving device of claim 1, wherein:
a first transmission hole corresponding to the first light guide hole among the plurality of first transmission holes completely overlaps the first light guide hole in the plan view; and
a first transmission hole corresponding to the second light guide hole among the plurality of first transmission holes only partially overlaps or does not overlap the second light guide hole in the plan view.

4. The light receiving device of claim 1, wherein a size of the first light guide hole in the plan view is less than a size of a first transmission hole corresponding to the first opening among the plurality of first transmission holes in the plan view.

5. The light receiving device of claim 1, wherein a size of the first light guide hole in the plan view is less than a size of the first opening in the plan view.

6. The light receiving device of claim 1, wherein an inner side of the first light guide pattern is surrounded by a boundary of the first opening in the plan view.

7. The light receiving device of claim 1, wherein a size of a first transmission hole corresponding to the first opening among the plurality of first transmission holes in the plan view is greater than a size of the first opening in the plan view.

8. The light receiving device of claim 1, wherein an inner side of a first light blocking pattern corresponding to the first opening among the plurality of first light blocking patterns surrounds a boundary of the first opening in the plan view.

9. The light receiving device of claim 1, wherein the optical layer further includes a second light blocking layer disposed between the first light blocking layer and the light guide layer in a thickness direction of the light receiving device, the second light blocking layer including a plurality of second light blocking patterns respectively including a plurality of second transmission holes.

10. The light receiving device of claim 9, wherein a size of a second transmission hole corresponding to the first opening among the plurality of second transmission holes in the plan view is greater than a size of the first light guide hole in the plan view.

11. The light receiving device of claim 9, wherein a size of each of the plurality of second transmission holes in the plan view is equal to a size of each of the plurality of first transmission holes in the plan view.

12. The light receiving device of claim 1, wherein an overlap area between the first opening and the first light guide hole in the plan view is greater than an overlap area between the second opening and the second light guide hole in the plan view.

13. The light receiving device of claim 1, wherein:
the pixel defining film further includes a third opening spaced apart from the first opening and the second opening,
the element layer includes an emission area defined by the third opening, and
the emission area emits light of an infrared wavelength.

14. The light receiving device of claim 13, wherein the plurality of first light blocking patterns, the first light guide pattern, and the second light guide pattern do not overlap the emission area in the plan view.

15. The light receiving device of claim 1, wherein the first light receiving area and the second light receiving area collect light of an infrared wavelength, respectively.

16. An automobile comprising:
a body; and
a first light receiving device disposed on the body,
wherein the first light receiving device includes:
a first substrate;
a first element layer disposed on the first substrate, the first element layer including a first pixel defining film including a first opening and a second opening and a first light receiving area and a second light receiving area respectively defined by the first opening and the second opening; and
a first optical layer disposed on the first element layer, the first optical layer including a first light blocking layer and a first light guide layer disposed on the first light blocking layer,
wherein the first light blocking layer includes a plurality of first light blocking patterns respectively including a plurality of first transmission holes,
wherein the first light guide layer includes a first light guide pattern including a first light guide hole corresponding to the first opening and a second light guide pattern including a second light guide hole corresponding to the second opening, and
wherein the first light guide hole overlaps the first opening in a plan view, and the second light guide hole is shifted in a first direction with respect to the second opening in the plan view.

17. The automobile of claim 16, further comprising a second light receiving device located in a second direction opposite to the first direction of the first light receiving device,
wherein the second light receiving device includes:
a second substrate;
a second element layer disposed on the second substrate, the second element layer including a second pixel defining film including a third opening and a fourth opening spaced apart from each other and a third light receiving area and a fourth light receiving area respectively defined by the third opening and the fourth opening; and
a second optical layer disposed on the second element layer, the second optical layer including a second light blocking layer and a second light guide layer disposed on the second light blocking layer,
wherein the second light blocking layer includes a plurality of second light blocking patterns respectively including a plurality of second transmission holes,
wherein the second light guide layer includes a third light guide pattern including a third light guide hole corresponding to the third opening and a fourth light guide pattern including a fourth light guide hole corresponding to the fourth opening, and
wherein the third light guide hole overlaps the third opening in the plan view, and the fourth light guide hole is shifted in the second direction opposite with respect to the fourth opening in the plan view.

18. The automobile of claim 16, wherein the first pixel defining film further includes a third opening located in a second direction opposite to the first direction with the first opening disposed between the second opening and the third opening in the plan view,
the first element layer further includes a third light receiving area defined by the third opening,
the first light guide layer further includes a third light guide pattern including a third light guide hole corresponding to the third opening, and
the third light guide hole is shifted in the second direction with respect to the third opening in the plan view.

19. The automobile of claim 16, wherein:
the first light guide hole completely overlaps the first light receiving area; and
the second light guide hole only partially overlaps or does not overlap the second light receiving area.

20. An electronic device, comprising:
a processor;
a memory having stored application programs for execution by the processor;
a light receiving device, comprising:
a substrate including a first area and a second area;
an element layer disposed on the substrate, the element layer including a pixel defining film including a first opening disposed in the first area and a second opening disposed in the second area and a first light receiving area and a second light receiving area respectively defined by the first opening and the second opening; and
an optical layer disposed on the element layer, the optical layer including a first light blocking layer and a light guide layer disposed on the first light blocking layer,
wherein the first light blocking layer includes a plurality of first light blocking patterns respectively including a plurality of first transmission holes,
the light guide layer includes a first light guide pattern including a first light guide hole corresponding to the first opening and a second light guide pattern including a second light guide hole corresponding to the second opening, and
the first light guide hole overlaps the first opening in a plan view, and the second light guide hole is shifted in one direction with respect to the second opening in the plan view.
